(19) United States
(12) Patent Application Publication
(10) Pub. No.: US 2026/0322392 A1
(43) Pub. Date: Oct. 15, 2026

(54) SYSTEMS AND METHODS FOR PERFORMING ANALOG TO MJPEG COMPRESSION USING TIME DOMAIN MIXED SIGNAL PROCESSING TECHNIQUES

(71) Applicant: Quasistatics Inc., West Lafayette, IN (US)

(72) Inventors: Shreyas Sen, West Lafayette, IN (US); Gourab Barik, West Lafayette, IN (US); Harshit Naman, West Lafayette, IN (US)

(21) Appl. No.: 19/179,229

(22) Filed: Apr. 15, 2025

(51) Int. Cl. H03M 1/12; H04N 19/124; H04N 19/129; H04N 19/625; H04N 19/93

(52) U.S. Cl. CPC H03M 1/124; H04N 19/124; H04N 19/129; H04N 19/625; H04N 19/93

(57) ABSTRACT

A system and method for performing analog-to-MJPEG compression using mixed-signal processing techniques is disclosed. The system includes a mixed-signal processing system which includes a multi-stage Discrete Cosine Transform (DCT) unit configured to compute multi-dimensional-DCT coefficients in analog domain. The mixed-signal processing system includes a clock generation unit to generate time pulses corresponding to the multi-dimensional-DCT coefficients and quantization matrix values. A time-domain multiply-accumulate (MAC) unit is to perform time-domain multiplication and division operations using the time pulses and a current signal to generate frequency-domain DCT outputs which implements the matrix multiplication of the DCT coefficient matrix with the analog input voltage values matrix. A quantization unit is configured to generate quantized outputs by performing element-wise division of the frequency-domain DCT outputs by a quantization matrix using capacitors and time domain weight pulses. The time domain weight pulses are equivalent to divisor values. The capacitors store the frequency-domain DCT outputs.

### TECHNICAL FIELD

Embodiments of the present disclosure generally relate to data compression systems, and more particularly relates to a system and method for performing analog to MJPEG compression using time domain mixed signal processing techniques.

### BACKGROUND

Analog-based processing schemes provide reduced power consumption compared to conventional digital processing methods while maintaining comparable functionality. The increasing prevalence of IoT applications has driven the widespread adoption of cameras across diverse sectors, including healthcare, autonomous vehicles, and energy-constrained environments such as battery-powered wearables. This proliferation has heightened the demand for low-power camera modules capable of operating efficiently in resource-limited settings.

Modern high-resolution cameras generate substantial data volumes, often on the order of gigabits per second (Gbps). For example, a 4K video at 12 frames per second produces approximately 1 Gbps of raw data. To manage this data within camera modules, such as those employing sensors like the SONY IMX317, lossy compression techniques, such as MJPEG or H.264, are typically utilized, reducing data rates to manageable levels (e.g., ~50 Mbps for MJPEG). MJPEG, in particular, provides lower latency and computational complexity than H.264, making it well-suited for real-time edge applications. However, traditional digital compression approaches face significant challenges, including: (1) high energy consumption by analog-to-digital converters (ADCs) due to the digitization of all image samples/pixels, (2) substantial intermediate data storage requirements, and (3) intensive computational demands for data compression. These factors render conventional digital compression less suitable for low-power edge camera systems.

Recent advancements in low-power camera imagers, such as the STM VD55G1, which consumes between 3-10 mW, have underscored the need for efficient compression techniques that minimize computational overhead. In traditional JPEG-based systems, power consumption is predominantly driven by the ADC, which converts analog image voltages into digital bits for every pixel, followed by compression in the digital domain. This process is both energy-intensive and area-inefficient due to the extensive use of registers and division blocks.

Prior solutions have explored direct analog-to-MJPEG compression using switched-capacitor circuits to perform arithmetic operations in the analog domain. These approaches reduce power consumption by limiting ADC activity to significant image samples. However, switched-capacitor-based implementations occupy larger chip areas, are susceptible to process variations, and support only low data rates, which restricts achievable frame rates.

FIG. 1A illustrates a block diagram of a standard digital signal processing-based camera node 100a, highlighting the conventional approach to camera systems. The primary objective of this work is to transition from high-power cameras with digital outputs, such as the Sony IMX 317, to more energy-efficient low-power camera solutions. In standard digital signal processing-based camera nodes, raw analog image samples are digitized into digital bits, followed by compression performed in the digital domain. For instance, a 4K video at 12 frames per second, utilizing 10-bit digitization, generates approximately 1 Gbps of data, resulting in significant storage and processing overheads. This conventional method relies on power-intensive analog-to-digital converters (ADCs) and digital signal processing (DSP) blocks, exacerbated by the digitization of all analog samples, which contributes to substantial processing and storage demands. Additionally, camera power consumption is heavily influenced by communication power, necessitating effective compression techniques. FIG. 1A depicts this standard architecture, featuring camera 102A, ADC 104A, digital signal processing 106A, and serializer 108A, emphasizing the challenges associated with high data rates and energy consumption in traditional digital camera systems.

FIG. 1B depicts a standard process 100B of performing JPEG image compression. The standard jpeg compression system 100b consists of the DCT block 112b which perform the time domain to frequency domain conversion. The DCT block 112b is followed by the quantization block 114b which divides the DCT block output by a standard Q-matrix 124b, this performs the compression and helps getting the significant samples. Followed by the quantization block is the zig-zag traversal block 116b which arranges the sample in the order such that the significant samples are in the front followed by the insignificant samples. Then finally, then run length encoder 118b performs the real compression such that the significant samples are sent for digitization and the insignificant samples are counted as zero and the count is digitized.

FIG. 1C depicts a standard DCT block 100C. The first step of the JPEG compression is the discrete cosine transform which converts the image data from the time domain to frequency domain. This helps sparsifies the input image. The DCT transform is performed by multiplying the input 8×8 image by an 8×8 DCT coefficient matrix as shown by the Y2D_DCT matrix.

FIG. 1D describes a possible application of low power cameras, the previous system architectures, and previous solution of direct analog to MJPEG compression using switched capacitor circuit are demonstrated. The previous implementation using switched capacitor-based MAC and division computation to perform MJPEG compression has the demerits that the SC-based circuit occupy larger area, are prone to process variation and can handle low data rate thereby limiting the frame rate that it can handle.

FIG. 1E depicts a graphical representation of Number of bits communicated/switched versus energy expenditure. Standard digital signal processing-based camera nodes, involve digitizing the raw analog samples from the image to digital bits and then perform compression in the digital domain. For example, a 4K 12 fps video using 10b digitization generates 1 Gbps of data, which leads to storage and processing overheads. After that the compression is performed in the digital domain. Basically, the standard digital based processing involves power hungry ADC and DSP blocks and has large processing and storage overheads, because of the digitization of all the analog samples. The camera power is also dominated by the communication power; hence the compression is necessary.

Conventional camera systems digitize all raw analog image samples, relying on power-intensive digital signal processing (DSP) blocks and analog-to-digital converters (ADCs) to compress the resulting high-volume data. This approach incurs significant processing and storage overheads, driven by the digitization of all samples and the subsequent compression in the digital domain. The need to further reduce total camera power consumption, in light of declining imager power, highlights the requirement for innovative solutions that address these inefficiencies, including the development of low-power analog compression techniques to mitigate the energy demands of traditional digital processing methods.

Therefore, there is a need in the art to provide a low power system and method for performing analog to MJPEG compression using time domain mixed signal processing techniques to address the aforementioned deficiencies in the art.

### SUMMARY

This summary is provided to introduce a selection of concepts, in a simple manner, which is further described in the detailed description of the disclosure. This summary is neither intended to identify key or essential inventive concepts of the subject matter nor to determine the scope of the disclosure.

An aspect of the present disclosure provides a processing system for performing analog-to-MJPEG compression using time domain mixed-signal processing techniques. The processing system includes a data acquisition unit configured to receive analog voltage signals corresponding to pixel data from at least one sensor node. Further, the processing system includes a mixed-signal processing system coupled to the data acquisition unit. The mixed-signal processing system includes a multi-stage Discrete Cosine Transform (DCT) unit configured to compute multi-dimensional-DCT coefficients corresponding to the pixel data in analog domain. The mixed-signal processing system further includes a clock generation unit configured to generate time pulses corresponding to the multi-dimensional-DCT coefficients and quantization matrix values. Furthermore, the mixed-signal processing system further includes a time-domain multiply-accumulate (MAC) unit configured to perform time-domain multiplication and division operations using the time pulses and a current signal to generate frequency-domain DCT outputs which implements the matrix multiplication of the DCT coefficient matrix with the analog input voltage values matrix. Additionally, the mixed-signal processing system further includes a quantization unit configured to generate quantized outputs by performing element-wise division of the frequency-domain DCT outputs by a quantization matrix using a plurality of capacitors and time domain weight pulses. The time domain weight pulses are equivalent to divisor values. The plurality of capacitors stores the frequency-domain DCT outputs.

Another aspect of the present disclosure includes a method for performing analog-to-MJPEG compression using time-domain mixed-signal processing techniques. The method includes receiving, by a data acquisition unit, analog voltage signals corresponding to pixel data from at least one sensor node. Further, the method includes computing, by a multi-stage Discrete Cosine Transform (DCT) unit, multi-dimensional DCT coefficients corresponding to the pixel data in an analog domain. Furthermore, the method includes generating, by a clock generation unit, time pulses corresponding to the multi-dimensional DCT coefficients and quantization matrix values. Further, the method includes performing, by a time-domain multiply-accumulate (MAC) unit, time-domain multiplication and division operations using the time pulses and a current signal to generate frequency-domain DCT outputs which implements the matrix multiplication of the DCT coefficient matrix with the analog input voltage values matrix. Additionally, the method includes generating, by a quantization unit, quantized outputs by performing element-wise division of the frequency-domain DCT outputs by the quantization matrix values using a plurality of capacitors and time domain weight pulses. The time domain weight pulses are equivalent to divisor values. The plurality of capacitors for storing the frequency-domain DCT outputs.

To further clarify the advantages and features of the present disclosure, a more particular description of the disclosure will follow by reference to specific embodiments thereof, which are illustrated in the appended figures. It is to be appreciated that these figures depict only typical embodiments of the disclosure and are therefore not to be considered limiting in scope. The disclosure will be described and explained with additional specificity and detail with the appended figures.

### BRIEF DESCRIPTION OF ACCOMPANYING DRAWINGS

The disclosure will be described and explained with additional specificity and detail with the accompanying figures in which:

FIGS. 1A-1E illustrates exemplary representations of traditional JPEG compression architecture, according to prior art;

FIG. 2 illustrates exemplary representations of time domain analog-to-MJPEG compression system, according to an example embodiment of the present disclosure;

FIGS. 3A-B illustrates exemplary block diagram representations of a network architecture for time domain analog-to-MJPEG compression, such as those shown in FIG. 2, according to an example embodiment of the present disclosure;

FIGS. 4A-D illustrates exemplary block diagram representations of the time-domain multiply-accumulate (MAC) unit, such as those shown in FIG. 3, depicting a complete flow of events for performing time-domain analog-to-jpeg compression using mixed-signal processing techniques, according to an example embodiment of the present disclosure;

FIG. 4E illustrates an example circuit diagram representation of the time-domain multiply-accumulate (MAC) unit, such as those shown in FIG. 3, depicting a complete flow of events for performing time-domain analog-to-jpeg compression using mixed-signal processing techniques, according to an example embodiment of the present disclosure;

FIGS. 5A-B illustrates exemplary block diagram representations of a clock generation unit comprising a 32-phase PLL, according to an example embodiment of the present disclosure;

FIG. 6 illustrates an exemplary timing diagram representation of a Time Domain (TD) MAC Computation Waveforms, according to an example embodiment of the present disclosure;

FIG. 7 illustrates example representations of time domain weight generation block, according to an example embodiment of the present disclosure;

FIG. 8 illustrates an exemplary timing diagram representation of simulation results of time domain DCT weights, according to an example embodiment of the present disclosure;

FIG. 9 illustrates an exemplary circuit diagram representation of an element-wise division unit, according to an example embodiment of the present disclosure;

FIGS. 10A-B illustrates an exemplary overall circuit diagram representation of time domain analog-to-jpeg compression system, according to an example embodiment of the present disclosure; and

FIG. 11 illustrates an example flow chart depicting a process of performing analog-to-MJPEG compression using mixed-signal processing techniques, according to an example embodiment of the present disclosure.

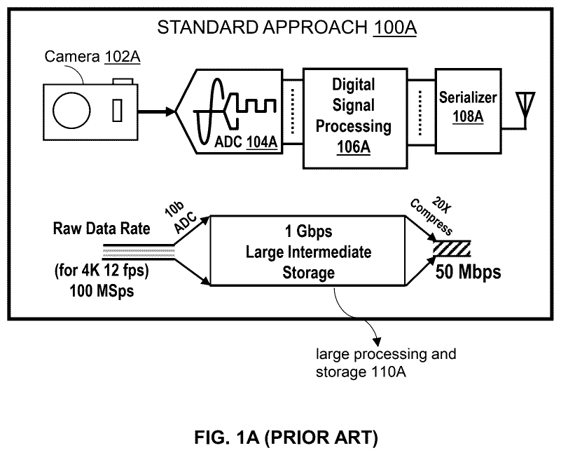

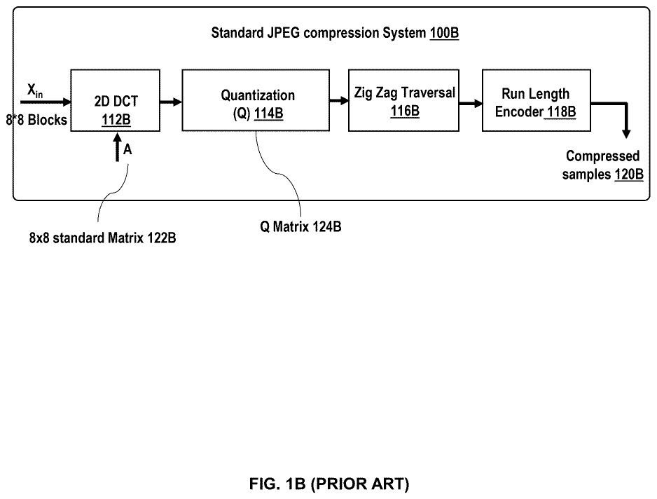

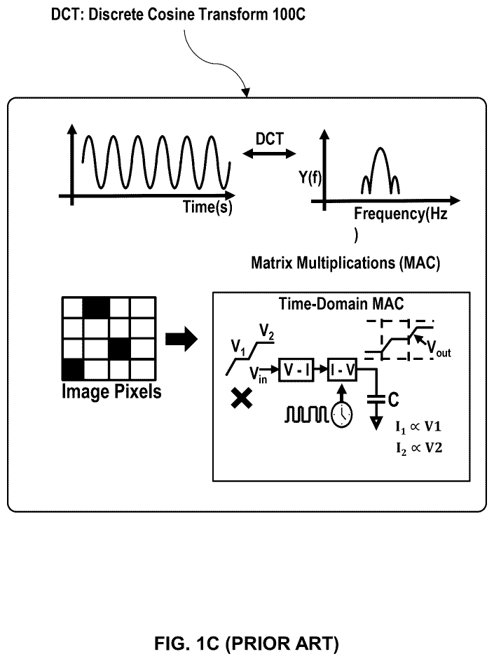

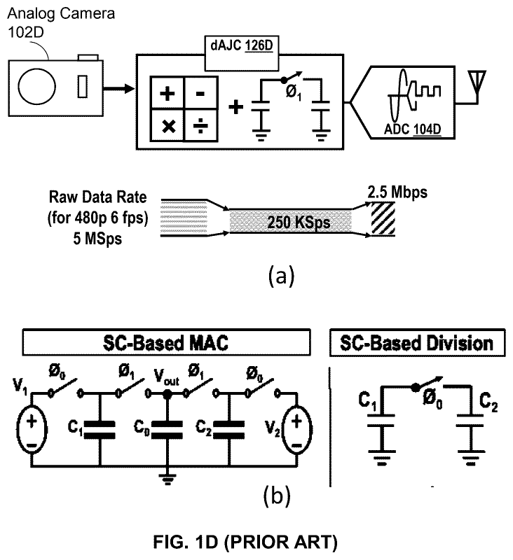

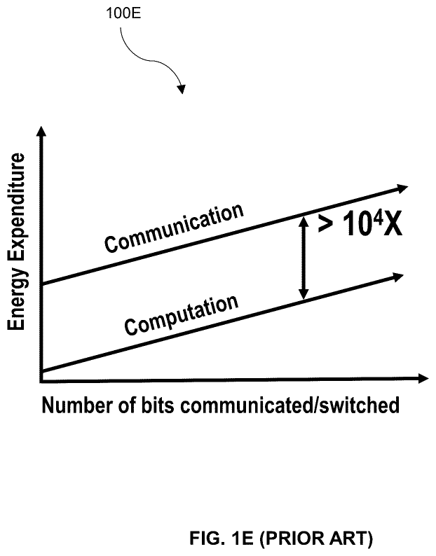

Further, those skilled in the art will appreciate that elements in the figures are illustrated for simplicity and may not have necessarily been drawn to scale. Furthermore, in terms of the construction of the device, one or more components of the device may have been represented in the figures by conventional symbols, and the figures may show only those specific details that are pertinent to understanding the embodiments of the present disclosure so as not to obscure the figures with details that will be readily apparent to those skilled in the art having the benefit of the description herein.

### DETAILED DESCRIPTION

For simplicity and illustrative purposes, the present disclosure is described by referring mainly to examples thereof. The examples of the present disclosure described herein may be used together in different combinations. In the following description, details are set forth in order to provide an understanding of the present disclosure. It will be readily apparent, however, that the present disclosure may be practiced without limitation to all these details. Also, throughout the present disclosure, the terms “a” and “an” are intended to denote at least one of a particular element. The terms “a” and “an” may also denote more than one of a particular element. As used herein, the term “includes” means includes but not limited to, the term “including” means including but not limited to. The term “based on” means based at least in part on, the term “based upon” means based at least in part upon, and the term “such as” means such as but not limited to. The term “relevant” means closely connected or appropriate to what is being performed or considered.

For the purpose of promoting an understanding of the principles of the disclosure, reference will now be made to the embodiment illustrated in the figures and specific language will be used to describe them. It will nevertheless be understood that no limitation of the scope of the disclosure is thereby intended. Such alterations and further modifications in the illustrated system, and such further applications of the principles of the disclosure as would normally occur to those skilled in the art are to be construed as being within the scope of the present disclosure. It will be understood by those skilled in the art that the foregoing general description and the following detailed description are exemplary and explanatory of the disclosure and are not intended to be restrictive thereof.

In the present document, the word “exemplary” is used herein to mean “serving as an example, instance, or illustration”. Any embodiment or implementation of the present subject matter described herein as “exemplary” is not necessarily to be construed as preferred or advantageous over other embodiments. The terms “comprise”, “comprising”, or any other variations thereof, are intended to cover a non-exclusive inclusion, such that one or more devices or sub-systems or elements or structures or components preceded by “comprises . . . a” does not, without more constraints, preclude the existence of other devices, sub-systems, additional sub-modules. Appearances of the phrase “in an embodiment”, “in another embodiment”, “in an exemplary embodiment” and similar language throughout this specification may, but not necessarily do, all refer to the same embodiment.

Unless otherwise defined, all technical and scientific terms used herein have the same meaning as commonly understood by those skilled in the art to which this disclosure belongs. The system, methods, and examples provided herein are only illustrative and not intended to be limiting. A computer system (standalone, client, or server, or computer-implemented system) configured by an application may constitute a “module” (or “subsystem”) that is configured and operated to perform certain operations. In one embodiment, the “module” or “subsystem” may be implemented mechanically or electronically, so a module includes dedicated circuitry or logic that is permanently configured (within a special-purpose processor) to perform certain operations. In another embodiment, a “module” or a “subsystem” may also comprise programmable logic or circuitry (as encompassed within a general-purpose processor or other programmable processor) that is temporarily configured by software to perform certain operations. Accordingly, the term “module” or “subsystem” should be understood to encompass a tangible entity, be that an entity that is physically constructed permanently configured (hardwired), or temporarily configured (programmed) to operate in a certain manner and/or to perform certain operations described herein.

Embodiments of the present disclosure provides a processing system for performing analog-to-MJPEG compression using time domain mixed-signal processing techniques. The processing system includes a data acquisition unit configured to receive analog voltage signals corresponding to pixel data from at least one sensor node. Further, the processing system includes a mixed-signal processing system coupled to the data acquisition unit. The mixed-signal processing system includes a multi-stage Discrete Cosine Transform (DCT) unit configured to compute multi-dimensional-DCT coefficients corresponding to the pixel data in analog domain. The mixed-signal processing system further includes a clock generation unit configured to generate time pulses corresponding to the multi-dimensional-DCT coefficients and quantization matrix values. Furthermore, the mixed-signal processing system further includes a time-domain multiply-accumulate (MAC) unit configured to perform time-domain multiplication and division operations using the time pulses and a current signal to generate frequency-domain DCT outputs which implements the matrix multiplication of the DCT coefficient matrix with the analog input voltage values matrix. Additionally, the mixed-signal processing system further includes a quantization unit configured to generate quantized outputs by performing element-wise division of the frequency-domain DCT outputs by a quantization matrix using a plurality of capacitors and time domain weight pulses. The time domain weight pulses are equivalent to divisor values. The plurality of capacitors stores the frequency-domain DCT outputs.

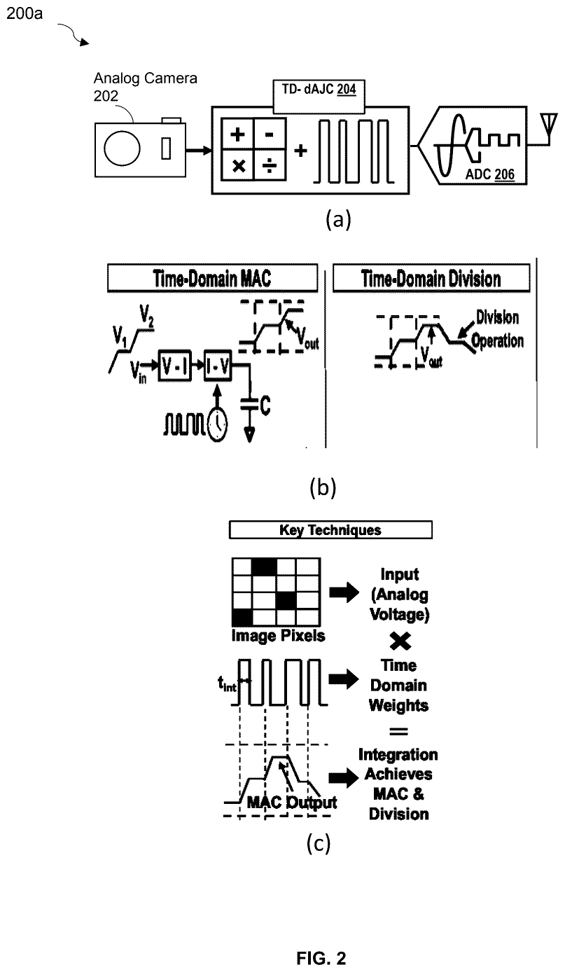

Referring now to the drawings, and more particularly to FIG. 2 through FIG. 11, where similar reference characters denote corresponding features consistently throughout the figures, there are shown preferred embodiments, and these embodiments are described in the context of the following exemplary system and/or method.

FIG. 2 illustrates exemplary representations of time domain analog-to-MJPEG compression system 200, according to an example embodiment of the present disclosure. Part (a) of FIG. 2 illustrates an example block diagram representation of a network architecture 200a capable of performing analog-to-MJPEG compression using time-domain mixed-signal processing techniques. The network architecture 200A comprises an analog camera 202, a time-domain mixed signal computing macro performing Analog to MJPEG Conversion (Td-dAJC) unit 204 and an analog to digital converter 206. The analog camera 202 (also referred herein as data acquisition unit 202) is configured to receive analog voltage signals corresponding to pixel data from at least one sensor node. The analog camera 202 may be a device that captures and records visual images as continuous electrical signals, representing variations in light intensity and color through analog waveforms. Unlike digital cameras, which convert these signals into discrete binary data, analog cameras process and store the image information in an analog format, typically on media such as videotape or film. The output signal is usually transmitted or recorded without digitization, requiring analog processing and playback systems for interpretation. Such captured images are transmitted to the Td-dAJC unit 204.

Alternatively, the analog camera 202 may be replaced by any other image capturing means such as, but not limited to, a camera. As used in this disclosure, a “analog camera 202” may be a device that is configured to sense electromagnetic radiation, such as without limitation visible light, and generate an image representing the electromagnetic radiation. In some cases, an analog camera 202 may include one or more optics. Exemplary non-limiting optics include spherical lenses, aspherical lenses, reflectors, polarizers, filters, windows, aperture stops, and the like. In some cases, at least a camera may include an image sensor. Exemplary non-limiting image sensors include digital image sensors, such as without limitation charge-coupled device (CCD) sensors and complimentary metal-oxide-semiconductor (CMOS) sensors, chemical image sensors, and analog image sensors, such as without limitation film. In some cases, the analog camera 202 may be sensitive within a non-visible range of electromagnetic radiation, such as without limitation infrared.

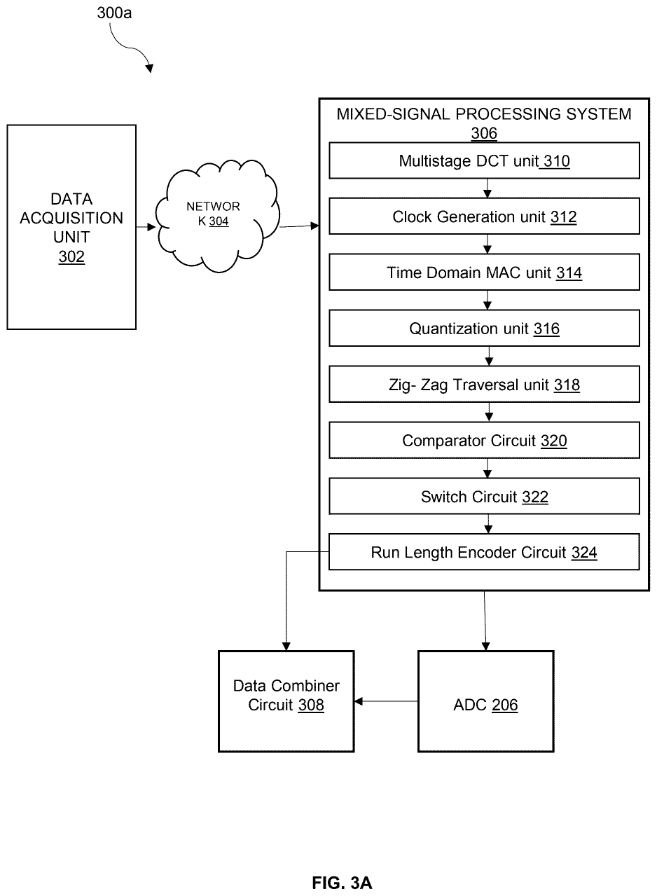

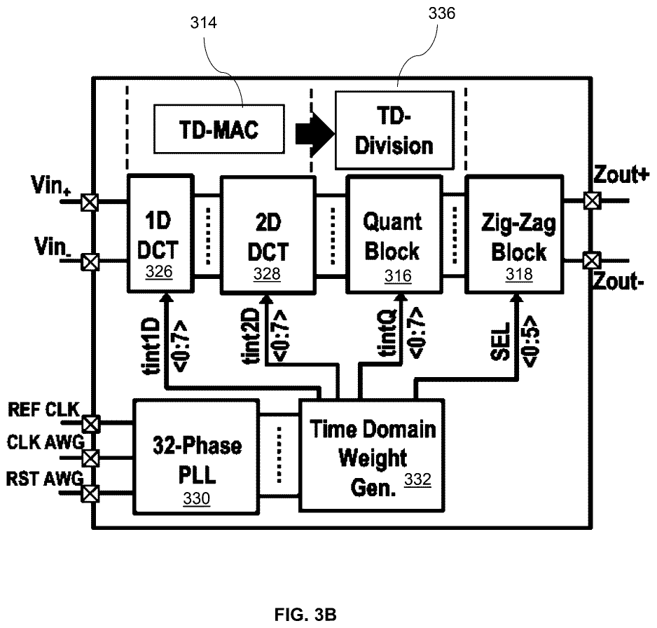

The Td-dAJC unit 204 (also referred herein as the mixed-signal processing system 204 or the system 204). The Td-dAJC unit 204 comprises a multi-stage Discrete Cosine Transform (DCT) unit configured to compute multi-dimensional-DCT coefficients corresponding to the pixel data in analog domain. Further, the Td-dAJC unit 204 comprises a clock generation unit configured to generate time pulses corresponding to the multi-dimensional-DCT coefficients and quantization matrix values. Furthermore, Td-dAJC unit 204 comprises a time-domain multiply-accumulate (MAC) unit configured to perform time-domain multiplication and division operations using the time pulses and a current signal to generate frequency-domain DCT outputs which implements the matrix multiplication of the DCT coefficient matrix and with the analog input voltage values matrix. Additionally, the Td-dAJC unit 204 comprises a quantization unit configured to generate quantized outputs by performing element-wise division of the frequency-domain DCT outputs by a quantization matrix using a plurality of capacitors and time domain weight pulses. The time domain weight pulses are equivalent to divisor values. The plurality of capacitors stores the frequency-domain DCT outputs. A detailed view of the Td-dAJC unit 204 is shown in FIG. 3A.

The TD-dAJC unit 204 is configured to perform Analog to MJPEG conversion in the Time Domain where the inputs are in voltage domain and the weights are mapped to time such that the MAC and division can be achieved using time domain integration as shown in part (c) of FIG. 2. The TD-dAJC technique maps DCT weights to time pulses extracted from a 32-Phase PLL (by XORing the selected phases), making the weights PVT invariant. PVT-tolerance of the integrating MAC is achieved using built-in current control, enhancing computed MAC accuracy as shown in part (c) of FIG. 2. Unlike SCs, the time domain technique eliminates the need for large capacitances and hence intermediate power-hungry buffers, making the present system 200a significantly lower area and lower power, while achieving 20× faster operation speeds (5 MSps [5] to 100 MSps). Time pulse-based computing makes the Td-dAJC unit 204 more suitable for lower-scale technology nodes compared to voltage or current-based analog techniques. The Td-dAJC unit 204 achieves a 25× improvement in energy per pixel compared to digital implementations and a 13× improvement over previous SC-based implementation with an increased frame size and frame rate.

Part (b) of FIG. 2 depicts components for the Td-dAJC unit 204 which includes, a linear Voltage to current (I) converter. The V-I converter converts the input image voltage signal to current. Further, the Td-dAJC unit 204 includes the current charges capacitors over digitally generated time pulses (from various phases of a 32-phase Phase Locked Loop (PLL)), storing the Discrete Cosine Transform (DCT) coefficients.

The ADC 206 may be consistently engaged in compression process, contributing to overall power requirements of the Td-dAJC unit 204.

In an exemplary embodiment, the system 204 may be a MJPEG compressor, such as, but not limited to, smartphone image processing units integrated into the system-on-chip (SoC) of smartphones, digital camera compression modules, embedded systems for surveillance and the like. In an example embodiment, the term “MJPEG compressor” or “the system 204” or “the Td-dAJC unit 204” or the “mixed signal mixed-signal processing system 204” may refer to both software algorithms and hardware components or accelerators that may assist in compression process.

FIGS. 3A-B illustrates exemplary block diagram representations of a network architecture 300a for time domain analog-to-jpeg compression, such as those shown in FIG. 2, according to an example embodiment of the present disclosure.

The network architecture 300a comprises data acquisition unit 302, a mixed-signal processing system 306, an Analog to Digital Converter (ADC) 206, and a data combiner circuit 308. The data acquisition unit 302 is connected to the mixed-signal processing system 306 via a network 304. The data acquisition unit 302 is similar to the analog camera 202, as shown in FIG. 2. The data acquisition unit 302 is configured to receive analog voltage signals corresponding to pixel data from at least one sensor node. In an example, the at least one sensor node may be an image sensor node.

The mixed-signal processing system 306 is similar to the Td-dAJC unit 204 as shown in FIG. 2. The mixed-signal processing system 306 is configured for performing analog-to-MJPEG compression using time domain mixed-signal processing techniques. The mixed-signal processing system 306 comprises a multi-stage Discrete Cosine Transform (DCT) unit 310, the clock generation unit 312, the time domain MAC unit 314, the quantization unit 316, the zig-zag traversal unit 318, a comparator circuit 320, the switch circuit 322, and the run-length encoder circuit 324. The multi-stage Discrete Cosine Transform (DCT) unit 310 is configured to compute multi-dimensional-DCT coefficients corresponding to the pixel data in analog domain. The clock generation unit 312 is configured to generate time pulses corresponding to the multi-dimensional-DCT coefficients and quantization matrix values. The time-domain multiply-accumulate (MAC) unit 314 is configured to perform time-domain multiplication and division operations using the time pulses and a current signal to generate frequency-domain DCT outputs which implements the matrix multiplication of the DCT coefficient matrix with the analog input voltage values matrix. The quantization unit 316 is configured to generate quantized outputs by performing element-wise division of the frequency-domain DCT outputs by a quantization matrix using a plurality of capacitors and time domain weight pulses. The time domain weight pulses are equivalent to divisor values. The plurality of capacitors stores the frequency-domain DCT outputs.

The zig-zag traversal unit 318 comprises an analog multiplexer and a digital controller. The zig-zag traversal unit 318 is configured to serialize the quantized outputs in an order prioritizing significant samples followed by insignificant samples. The comparator circuit 320 is configured to compare the serialized output to distinguish significant samples from insignificant samples based on a threshold value; and generate a control signal for selective digitization. The switch circuit 322 is configured to activate an analog-to-digital converter (ADC) 206 for the significant samples as determined by the comparator circuit 320 and power gate the ADC 206 for insignificant samples. Further, the run-length encoding circuit 324 is configured to count occurrences of the insignificant samples using a counter and output a count value representing the insignificant samples.

The analog-to-digital converter (ADC) 206 is configured to selectively digitize the significant samples based on the control signal from the comparator circuit 320. The data combiner circuit 308 is configured to multiplex outputs of the ADC 206 and the run-length encoding circuit 324 is configured to generate a MJPEG compressed digital output.

The time-domain multiply-accumulate (MAC) unit 314 comprises a voltage-to-current conversion circuit (as shown in FIG. 2). The voltage-to-current conversion circuit is configured to convert the analog voltage signals to an output current with a linear voltage-to-current relationship. The output current is multiplied by a corresponding DCT coefficient and stored in a capacitor associated with respective coefficient. The voltage-to-current conversion circuit comprises an NMOS transistor configured to convert the analog voltage signals to the output current. The NMOS transistor operates over an input voltage range from below a reference voltage to a minimum voltage of a DC power supply. Further, the voltage-to-current conversion circuit comprises a source degeneration resistor connected to a source terminal of the NMOS transistor. The source degeneration resistor provides resistance for linear voltage-to-current conversion.

The mixed-signal processing system 306 further comprises a capacitor circuit (not shown) configured to store analog charge based on the output current. Further, the mixed-signal processing system 306 comprises a current mirror circuit configured to replicate the output current from the voltage to current conversion. Furthermore, the mixed-signal processing system 306 comprises a switch circuit configured to regulate the output current to the capacitor circuit based on the time pulses.

The capacitor circuit comprises a plurality of capacitors configured to store analog charge proportional to the output current regulated by the switch circuit. The output current is multiplied by a corresponding DCT coefficient and stored in a corresponding capacitor associated with respective DCT coefficient. Further, the capacitor circuit comprises an integration module configured to accumulate the analog charge proportional to the input voltage over a duration of the time pulses proportional to the weights. The plurality of capacitors is further configured to store a result of a division operation by subtracting a portion of an input value based on a quantization coefficient.

The switch circuit comprises a plurality of switches each coupled between the voltage-to-current conversion circuit and a respective capacitor of the capacitor circuit. Further, the switch circuit comprises a control module configured to open and close the plurality of switches based on the time pulses.

In an embodiment, the time-domain multiply-accumulate (MAC) unit 314 is configured to perform one multiplication and accumulation operation for a plurality of operands in plurality of clock cycles to generate the frequency-domain DCT outputs. The frequency-domain DCT outputs are proportional to accumulated charge on corresponding capacitors of the capacitor circuit.

The quantization unit 316 is configured to sample the frequency-domain DCT outputs of the time-domain multiply-accumulate (MAC) unit using a sampling rate; and perform a division operation by charging the capacitor circuit to subtract a portion of the sampled output based on a quantization matrix. The quantization unit 316 reuses a capacitor of the capacitor circuit of the DCT stage to store a result of the division operation and operates in three phases. The quantization unit 316 operates in three phases, a first phase, which is a sampling phase to sample a voltage from the frequency-domain DCT outputs of the time-domain multiply-accumulate (MAC) unit; a second phase which is an integration module to convert the sampled voltage to a current and charge the capacitor; and a third phase, a reset phase to reset a capacitor circuit to zero.

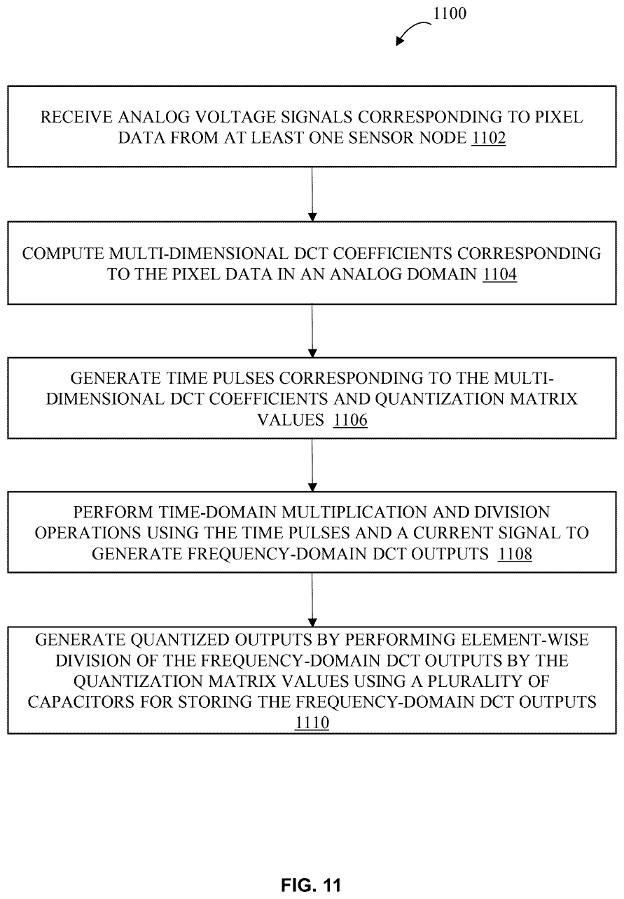

In an embodiment, the time-domain multiply-accumulate (MAC) unit 314 comprises a first stage comprising a plurality of pseudo-differential MAC units. The plurality of pseudo-differential MAC units is configured to compute a one-dimensional DCT (1D-DCT) for one column of a N*N image block in a plurality of clock cycles. The time-domain multiply-accumulate (MAC) unit 314 further comprises a second stage comprising a plurality of first-stage units configured to compute a two-dimensional DCT (2D-DCT) for the N*N image block in the plurality of clock cycles. A detailed view of the time-domain multiply-accumulate (MAC) unit 314 is shown in FIG. 11. The plurality of pseudo-differential MAC units are configured to process the analog voltage signals corresponding to positive and negative DCT coefficients. In an example embodiment, for a positive DCT coefficient, a first input voltage (Vin+) is connected to a positive input (VINP) and a second input voltage (Vin−) is connected to a negative input (VINN). For a negative DCT coefficient, the first input voltage (Vin+) is connected to the negative input (VINN) and the second input voltage (Vin−) is connected to the positive input (VINP).

In an example embodiment, the clock generation unit 312 is configured to generate at least one of input sampling clocks, DCT weight time pulses for 1D-DCT operations at each cycle of a base clock, and DCT weight time pulses for 2D-DCT operations at each N cycles of the base clock. The time pulses embed information of a DCT matrix and a quantization matrix.

In an example embodiment, the capacitor circuit is configured to perform multiplication and division operations by segmenting a multiplication operation into multiple addition operations; and segmenting a division operation into multiple subtraction operations, using the plurality of pseudo-differential MAC units with switching between sampling capacitors.

In an example embodiment, the clock generation unit 312 comprises an on-chip Phase-Locked Loop (PLL) configured to generate multiphase clock signals. Further, the clock generation unit 312 comprises a digital circuit configured to receive the multiphase clock signals and generate the time pulses corresponding to values of a Discrete Cosine Transform (DCT) matrix.

According to FIG. 3B, the time-domain multiply-accumulate (MAC) unit 314 comprises a 1D-DCT 326 and 2D-DCT 328 stages which perform the time domain to frequency domain conversion of the input image (8×8) blocks using the standard (8×8) DCT matrix. This is followed by the quantization unit 316 which performs the compression, by dividing the 2D DCT output by a quantization matrix. All the MAC computations in the DCT block and the division for quantization operation are performed in the time domain using the time-based weights from the clocking circuits and the time domain integration. Lastly, the analog values are arranged in using the zig-zag block 318 for arranging the compressed values in the order of significant values first followed by the insignificant values, hence, to perform the run-length encoding. The other figure shows the chain of steps for generating the digital control signals and integration times. An on-chip 32 phase 100 MHz PLL 330 may be used to generate a multiphase clock signal for the analog computation block. PLL 330 is followed by a clock divider block to provide flexibility for the circuit to operate at multiple frequencies. Clock divider output goes to the synchronizer 332, synchronizer block 332 takes an external clock to synchronize the incoming analog data with the on-chip clock. A manually tuned mux is provided as a parallel path to the synchronizer for brute force tuning of the clock phase. The final clock phases are fed to 1D and 2D DCT integration time generators, quantization unit 316, zig-zag traversal select bit generators and other digital control blocks.

Though few components and subsystems are disclosed in FIGS. 3A and 3B, there may be additional components and subsystems which is not shown, such as, but not limited to, ports, routers, repeaters, firewall devices, network devices, databases, network attached storage devices, user devices, additional processing systems, servers, assets, machineries, instruments, facility equipment, any other devices, and combination thereof. The person skilled in the art should not be limiting the components/subsystems shown in FIG. 3A-B. Although FIG. 3A-B illustrates the system 300, is connected to the data acquisition unit 302, one skilled in the art may envision that the system 300, may be connected to several data acquisition units, located at same/different locations.

Those of ordinary skilled in the art will appreciate that the hardware depicted in FIG. 3A may vary for particular implementations. For example, other peripheral devices such as an optical disk drive and the like, local area network (LAN), wide area network (WAN), wireless (e.g., wireless-fidelity (Wi-Fi)) adapter, graphics adapter, disk controller, input/output (I/O) adapter also may be used in addition or place of the hardware depicted. The depicted example is provided for explanation only and is not meant to imply architectural limitations concerning the present disclosure.

Those skilled in the art will recognize that, for simplicity and clarity, the full structure and operation of all data processing systems suitable for use with the present disclosure are not being depicted or described herein. Instead, only so much of the system 300 as is unique to the present disclosure or necessary for an understanding of the present disclosure is depicted and described. The remainder of the construction and operation of the system 300 may conform to any of the various current implementations and practices that were known in the art.

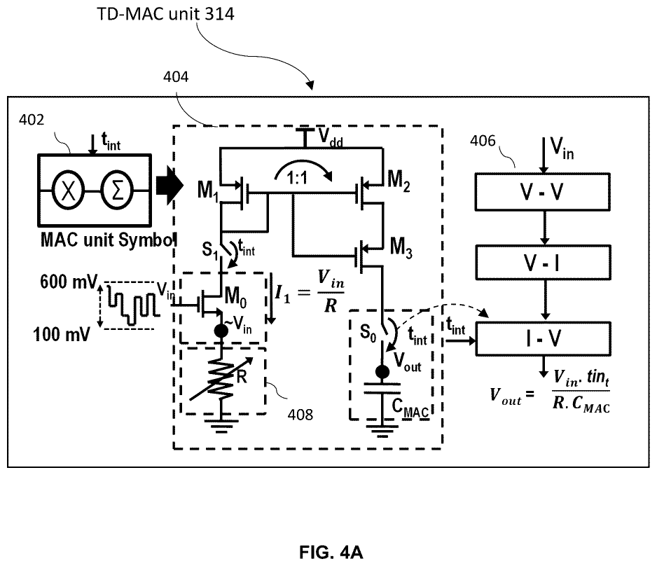

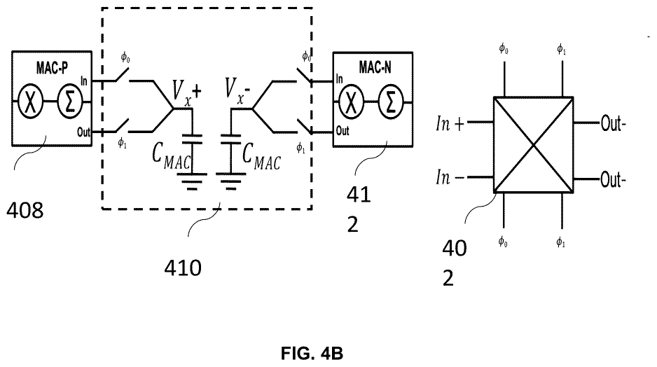

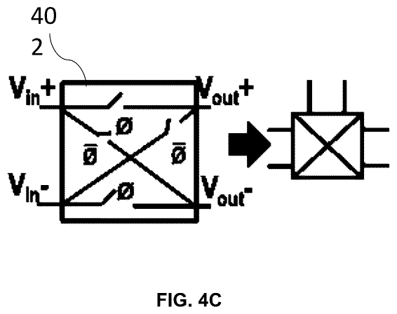

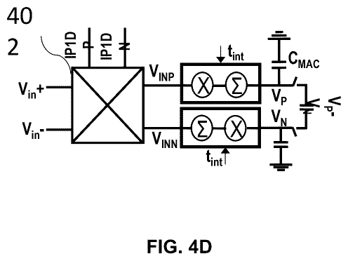

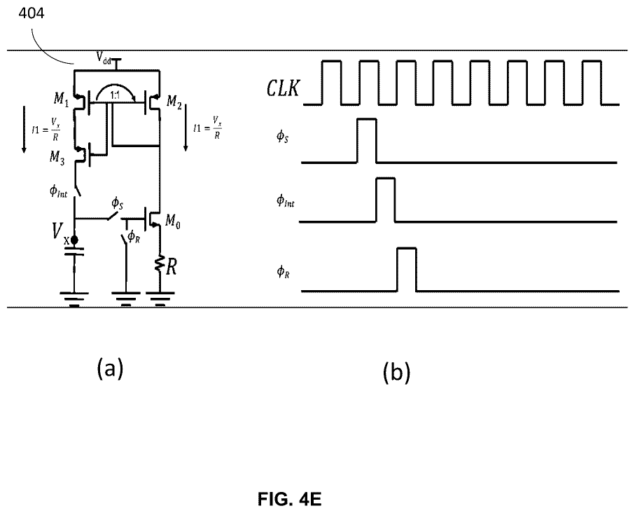

FIGS. 4A-B illustrates exemplary block diagram representations of the time-domain multiply-accumulate (MAC) unit 314, such as those shown in FIG. 3, depicting a complete flow of events for performing time-domain analog-to-MJPEG compression using mixed-signal processing techniques, according to an example embodiment of the present disclosure. As shown in FIG. 4A, a source-degenerated native NMOS (M0) 408 is used for linear voltage-to current (V-I) conversion 406, with Vth~0 mV, allowing an input swing of (Vdd/2) which helps maintain a high SNR as the signal traverses through MAC stages 404. The output swing is matched to input swing (unity gain), eliminating the need for buffers. The resistor (R) is adjusted to compensate for process variations in the V-I conversion ratio and capacitor value. The input voltage signal is converted from V-I using M0 and mirrored using cascaded current mirror and is integrated on a capacitance CMAC, for a specific time proportional to the DCT weight. Switches S1 and S0 are closed during the DCT weight time pulse, leading to multiplication. M3 acts as a cascade device making the integration current less sensitive to (VOUT). After multiplication, S0 and S1 open, reducing static current during idle phases. Unit switch circuit diagram 402 is shown in FIG. 4C which has crossed input switches for appropriate connection for signed coefficient. Input current charges the output capacitor when the integration time pulses (tint) are high, this charge gets accumulated on the capacitor increasing the voltage on the output capacitor (V=Q/C). The proposed MAC cell 402 takes 8 clock cycles to complete 1 MAC operation for 8 operands. The final voltage at the output cap after 8 clock cycles is given by VM. As shown in FIG. 4B, for positive DCT coefficient Vin+ is connected to VINP and Vin− to VINN, for negative coefficient the connection is vice versa, using the Pseudo-differential MAC for signed coefficients. For integration, the signal is always connected to Vin+ and the common mode voltage is provided to Vin−. The time-domain multiply-accumulate (MAC) unit 314 converts multiplication to addition and division to subtraction. In-situ MAC operation is realized by sampling the voltage to the input of MAC unit 314 and integrating the current over the same input capacitor. Input is sampled in phase φ₀ and integrated in phase φ₁. In-situ division provides 2× area benefit. Multiplication by a factor β>1,

Vₒᵤₜ=(Vₓ₊+α·Vₓ₊)−(Vₓ₋+α·Vₓ₋),β=1+α equation (1)

Multiplication by a factor β<1,

Vₒᵤₜ=(Vₓ₊+α·Vₓ₋)−(Vₓ₋+α·Vₓ₊),β=1−α equation (2)

In an example, mode of operation may be switched by appropriate cross connection of caps to the input of the MAC unit 314.

In FIG. 4B, the quantization step of JPEG compression algorithm requires elementwise division operation of the 2D-DCT output with a constant quantization matrix. This can be achieved using MAC unit 314 explained in FIG. 2. However, using a separate MAC unit 314 for quantization may lead to an increase in area by 2× because the two MAC capacitors for DCT operation and quantization operation. To optimize the area, division operation is performed in-situ on the capacitor that stores the 2D-DCT output, without using any extra capacitor. In-situ multiplication and division operation are realized by breaking a multiplication operation into multiple addition operations and breaking a division operation into multiple subtraction operations, respectively. All the MAC operations are realized in a pseudo-differential architecture 410. Addition/subtraction is realized by switching between Vx+ and Vx− sampling capacitors. In-situ division/multiplication, as shown in FIG. 4E, takes place in 3 phases, in φₛ phase voltage from Vx is sampled from the output capacitor to the gate of M0 transistor. During Mint phase, the sampled voltage is converted to current and is used to charge the output capacitor to the resultant voltage after Multiplication/Division operation. During φ_{R} phase, the gate of M0 transistor is then reset to 0.

For implementing the positive DCT coefficients 408 and negative DCT coefficients 412, a pseudo-differential architecture as shown in FIG. 4D is used. FIG. 4D illustrates an exemplary block diagram representation of a Pseudo-Differential (PD)-MAC Computation block 402 to cancel Common Mode noise, according to an example embodiment of the present disclosure. Here, for positive DCT coefficient Vin+ is connected to VINP and Vin− to VINN, for negative coefficient the connection is vice versa, using the Pseudo-differential MAC for signed coefficients. For integration, the signal is always connected to Vin+ and the common mode voltage is provided to Vin−. For the positive coefficients, the integration is in the positive direction however, for negative coefficients t3 and t4, the integration is negative to implement the negative coefficients. Apart from this the differential architecture reduces the common mode coupling. The pseudo-differential architecture helps in realizing negative DCT coefficients. It also reduces common mode coupling.

$${V}_{OUT} = \frac{{V}_{1} {t}_{1}}{R . CMAC} + \frac{{V}_{2} {t}_{2}}{R . CMAC} - \frac{{V}_{3} {t}_{3}}{R . CMAC} - \frac{{V}_{4} {t}_{4}}{R . CMAC} + \frac{{V}_{5} {t}_{5}}{R . CMAC} + ⋯ + \frac{{V}_{8} {t}_{8}}{R . CMAC} \qquad equation ( 3 )$$

FIG. 4E illustrates an example circuit diagram 404 representation of the time-domain multiply-accumulate (MAC) unit, such as those shown in FIG. 3, depicting a complete flow of events for performing time-domain analog-to-jpeg compression using mixed-signal processing techniques, according to an example embodiment of the present disclosure.

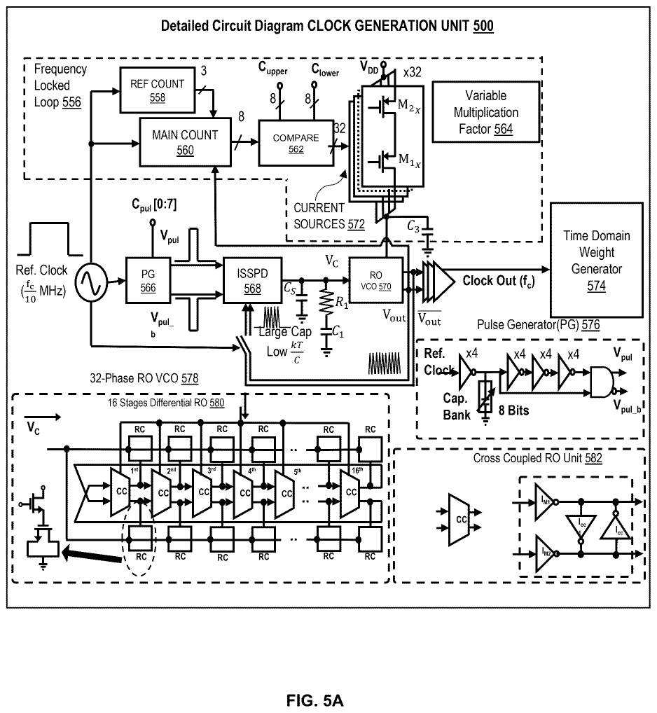

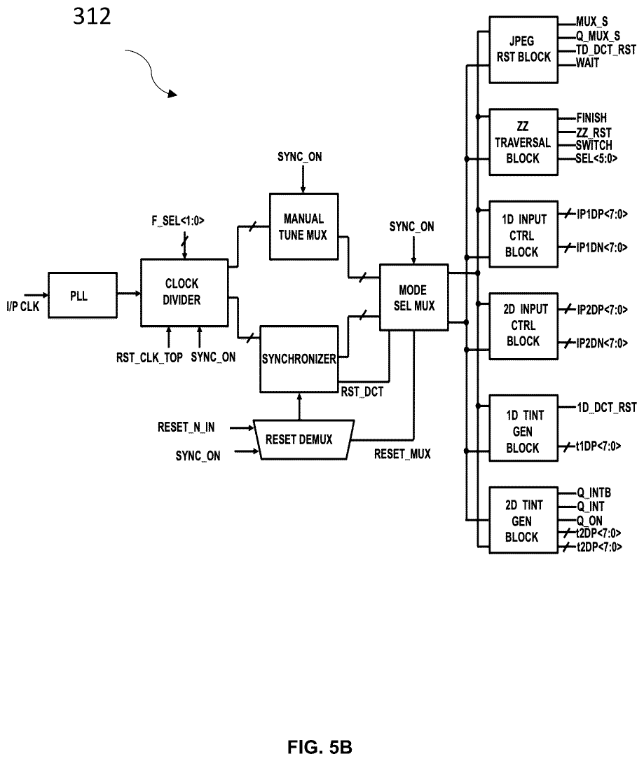

FIGS. 5A-B illustrates exemplary block diagram representations of a clock generation unit 500 comprising a 32-phase PLL, according to an example embodiment of the present disclosure. According to FIG. 5A, a schematic of the 32-phase PLL used is shown. For the 32-phase, a 16-stage differential ring oscillator based VCO is used. FIG. 5A depicts a Time-Domain Discrete Approximate MJPEG Compression (TD-dAJC) unit 204, leveraging a 32-phase Phase-Locked Loop (PLL) for efficient analog computation. The Frequency Locked Loop 556 represents the overall frequency control mechanism, ensuring the system maintains a stable output frequency. The Frequency Locked Loop 556 includes a feedback loop to lock the frequency. Further, a Pulse Generator (PG) 576 generates initial time pulses based on the input from the frequency locked loop 556 and feeds into the 32-Phase Ring Oscillator (RO) VCO 578 for further processing. The Voltage-Controlled Oscillator (VCO) 570 converts the control voltage (Vc) from the ISSPD 568 and LFE (Integrated Self-Sampling Phase Detector & Loop Filter) into a frequency output. Further, the Voltage-Controlled Oscillator (VCO) 570 drives the 32-phase RO structure. The 32-Phase RO VCO (Fine and Coarse Control) 578 comprises a 32-stage differential ring oscillator (RO) 580 with 16 RC stages, providing fine and coarse frequency control. Each stage (1st to 32nd) uses cross-coupled (CC) inverters 582 to generate 32 distinct phases. The RC networks stabilize the oscillation frequency.

The Variable Multiplication Factor 564 adjusts the target frequency (0.9-0.95 times the input frequency) using transistors M1x and M2x. This block 564 ensures precise frequency multiplication for phase generation.

The Pulse Generator (PG) 566 takes the reference clock and capacitor bank (8-bit control) to generate multiple output pulses (Vpul_a, Vpul_b). The Pulse Generator 576 (PG) uses a series of delay elements to create time pulses for downstream processing.

The Cross-Coupled RO Unit 582 contains main inverters (Im) and cross-coupled inverters (Icc) to sustain oscillation. The Cross-Coupled RO Unit 582 produces the differential signals required for the 32-phase output.

In an example embodiment, the clock generation unit 312 starts with a voltage input (Vc) processed by the ISSPD 568 & LFE, which feeds into the 32-Phase RO VCO 578. This VCO, controlled by fine and coarse RC networks, generates 32 unique phases. The VCO output is modulated by the variable multiplication factor block, adjusting the frequency to the target range (0.9-0.95 times the input). The PG 566 converts these phases into time pulses, utilizing a capacitor bank and delay elements to produce Vpul_and Vpul_b. These pulses are used to charge capacitors, storing DCT coefficients. An XOR gate-based weight generator extracts 7 unique time pulses from selected phases, mapping them to DCT weights for PVT (Process, Voltage, Temperature) invariance. The pulses drive Multiply-Accumulate (MAC) units for DCT and quantization operations, with built-in current control enhancing accuracy. Quantization divides values by a matrix (Q50) to control compression and image quality. An on-chip 100 MHz PLL generates the multiphase clock, followed by a clock divider for flexibility. A synchronizer aligns the analog data with the on-chip clock, with a manual mux for phase tuning. The final phases feed into DCT integration, quantization, and control blocks.

This TD-dAJC unit 204 achieves a 25× energy improvement per pixel over digital implementations and 13× over previous switched-capacitor (SC) methods, with 20× faster operation (5 MSps to 100 MSps). The TD-dAJC unit 204 eliminates large capacitances and buffers, reducing area and power while supporting lower-scale technology nodes through time-pulse-based computing.

The Reference Clock located in the Pulse Generator (PG) block serves as the input clock signal that initiates the pulse generation process. The RC block 558 drives the capacitor bank (8-bit control) and delay elements to produce multiple output pulses (Vpul_a, Vpul_b). The RC ensures synchronization with the external analog data via the synchronizer block. The Main Inverters are the primary inverters (Im1, Im2) that form the core of the ring oscillator (RO) structure. The main inverters work in conjunction with cross-coupled inverters (Icc) to sustain oscillation and generate differential signals across the 32 phases.

The Time Domain Weight Generator 574 utilizes an XOR gate-based mechanism to extract 7 unique time pulses from the 32 phases generated by the PLL. These pulses correspond to the 7 unique values in the Discrete Cosine Transform (DCT) weight matrix. The Time Domain Weight Generator 574 maps DCT weights to time pulses (tint), ensuring Process, Voltage, Temperature (PVT) invariance by leveraging the stable phase outputs. Further, the Time Domain Weight Generator 574 Feeds the generated weights to the MAC units for DCT and quantization operations.

FIG. 5B depicts a detailed view of the clock generation unit 312. The clock generation unit 312 comprises a PLL (Phase-Locked Loop), which receives the input clock (I/P CLK) and generates a stable multiphase clock signal. Further, the clock generation unit 312 comprises a clock divider which takes the PLL output and divides the clock frequency to provide flexibility for different operating frequencies. Further, the clock divider outputs are synchronized with the system via the “SYNC ON” signal.

The clock generation unit 312 further comprises a synchronizer which aligns the divided clock signal with the system timing. Further, the synchronizer receives RST_CLK_TOP and SYNC_ON inputs to ensure proper synchronization of the clock with external data.

The manual tune MUX allows manual adjustment of the clock phase using the F_SEL [1:0] input. Furthermore, the MUX provides a parallel path for brute-force tuning of the clock signal, enhancing flexibility.

The mode select MUX selects the operating mode based on the SYNC_ON signal and routes the synchronized clock to the appropriate downstream blocks.

The reset demux manages reset signals (RESET_N_IN and RST_DCT) with SYNC_ON and distributes reset commands to ensure proper initialization of the system. The reset mux further processes the reset signals from the reset demux and feeds the reset (RST) to various control blocks for coordinated operation.

The 1D input control block handles 1D input data processing (IP1DP<7:0> and IP1DN<7:0>) and manages the input signals for the 1D Discrete Cosine Transform (DCT) computation. The 2D input control block processes 2D input data (IP2DP<7:0> and IP2DN<7:0>) and prepares the data for 2D DCT and quantization operations.

The Zig Zag Traversal Block performs zigzag traversal of the DCT coefficients and outputs signals such as FINISH, ZZ_RST, and SEL<5:0> for ordering the coefficients.

The JPEG RST Block executes the final JPEG compression steps and outputs MUX_S, Q_MUX_S, TD_DCT_RST, and WAIT signals to control the compression process.

The 1D Tint Gen Block generates 1D integration time pulses (tint) for DCT computation and outputs 1D_DCT_RST and 1DP<7:0> for 1D processing.

The 2D Tint Gen Block generates 2D integration time pulses (tint) for DCT and quantization and outputs Q_INTB, Q_INT, 2DP<7:0>, and 2DP<7:0> for 2D processing.

In an example embodiment, the process begins with the PLL receiving the I/P CLK, generating a stable clock signal. This is divided by the Clock Divider to adjust the frequency. The Synchronizer aligns the divided clock with the system using RST_CLK_TOP and SYNC_ON, ensuring timing coherence with external data. The Manual Tune MUX allows fine-tuning of the clock phase via F_SEL [1:0], with the Mode Select MUX routing the signal based on the selected mode. The Reset Demux and Reset Mux distribute reset signals (RESET_N_IN and RST_DCT) to initialize the system components. The 1D Input Control Block and 2D Input Control Block process 1D and 2D input data (IP1DP/IP1DN and IP2DP/IP2DN), preparing it for transformation. The 1D Tint Gen Block and 2D Tint Gen Block generate time pulses (tint) for 1D and 2D DCT computations, outputting processed data (1DP<7:0>, 2DP<7:0>). The ZZ Traversal Block organizes the DCT coefficients in a zigzag pattern, while the JPEG Block finalizes the compression, outputting control signals (MUX_S, Q_MUX_S, TD_DCT_RST, WAIT). The system ensures synchronized operation across blocks, leveraging the PLL-derived clock and reset mechanisms to support the TD-dAJC's high-speed, low-power JPEG compression. This architecture enhances the TD-dAJC system's efficiency by providing precise clock management and data flow, supporting its 20× speed increase (5 MSps to 100 MSps) and significant energy savings.

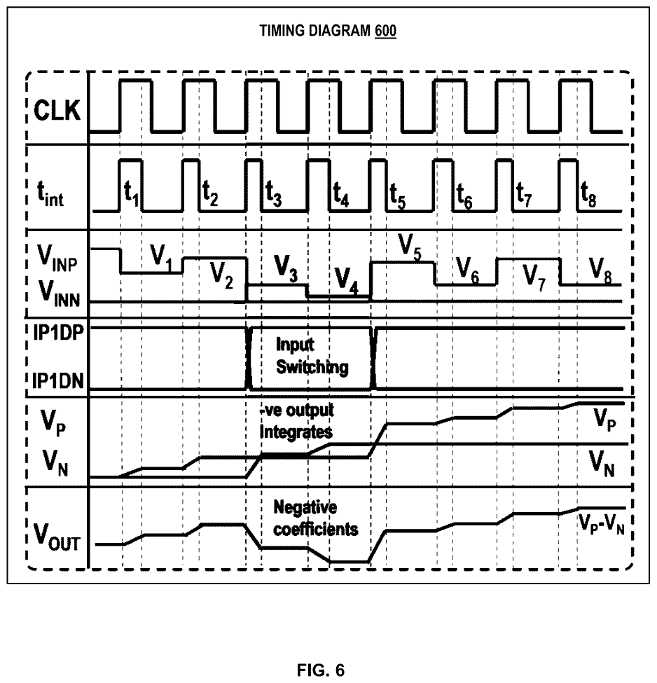

FIG. 6 illustrates an exemplary timing diagram representation of a Time Domain (TD) MAC Computation Waveforms 600, according to an example embodiment of the present disclosure. FIG. 6 depicts the waveform of a MAC operation over 8 clock cycles. The time domain MAC operation is shown in the final computed Vout at the end of 8 cycle, where both positive and negative coefficient values (t3 and t4) working have been shown.

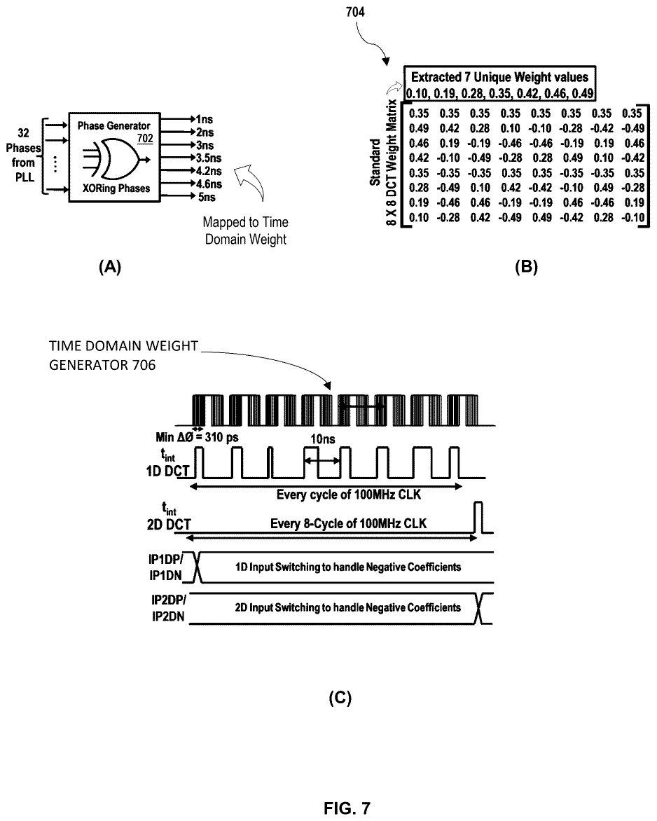

FIG. 7 illustrates example representations of time domain weight generation block, according to an example embodiment of the present disclosure. Part (a) of FIG. 7 depicts a phase generator 702. An On-chip PLL and digital core 702 generates tint integration time pulses or the time domain weights (tint) proportional to DCT coefficients. Selected phases from the 32-phases from the PLL 702 are used by an XOR gate-based weight generator 706 to create 7-unique time pulses 704 corresponding to each 7-unique value in DCT weight matrix. These pulses 704 are then directed to the MAC units for the DCT and Quantization operation. The values are element-wise divided by a quantization matrix (Q50), which controls compression ratio and image quality. The TD-dAJC unit 204 operates on 8×8 blocks of pixel values, applying the 2D Discrete Cosine Transform (DCT) to each block. The standard DCT transformation matrix for an 8×8 block is given here. The 32-phases PLL is used to get those 32-phases. Each of the 32-phases are separated by 310 ps. Then using appropriate phases and XORing them, the time domain weights are generated. The time domain weight values corresponding to the 7 specific DCT coefficient is shown on part (b) of FIG. 7. Apart from the DCT weights, the clocking circuit generates those DCT weights for 1D-DCT operation every cycle of the 100 MHz clock and the DCT weights for 2D-DCT operation every 8 cycles of the 1D-DCT operation as shown in part (c) of FIG. 7. The clocking circuit also generates the input switching at both 1D DCT and 2D DCT to implement the negative DCT coefficients.

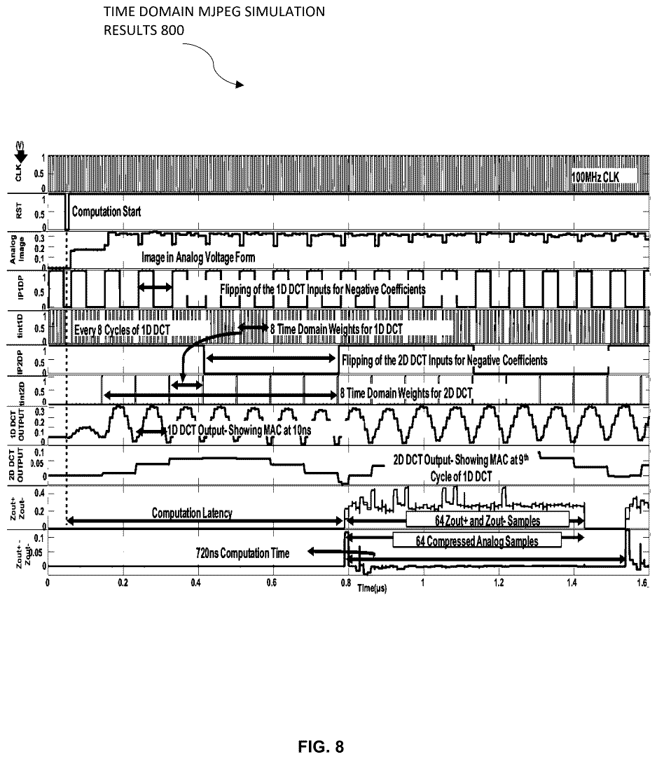

FIG. 8 illustrates an exemplary timing diagram representation of simulation results 800 of time domain DCT weights, according to an example embodiment of the present disclosure. FIG. 8 shows the timing diagrams of output of steps of the MJPEG compression. FIG. 8 shows the main clock operating at 100 MHz. The computation starts with the reset signal when the input image pixels are sent. The IP1DP and IP1DN show the input switching clocks which switch based on the coefficient's signs and control the pseudo-differential MAC operation. The tint1D and tint2D show the time domain DCT weights, where the 1D DCT weights are present every cycle of the 100 MHz clock and the 2D DCT weights are present every other 8 cycles of the 1D DCT clock, having 8× lower frequency. The final computed output is shown in Zout+ and Zout−, and taking the difference gives the final compressed samples values arranged in the zig-zag manner which is then used by the post processing to regenerate the original image from the compressed samples.

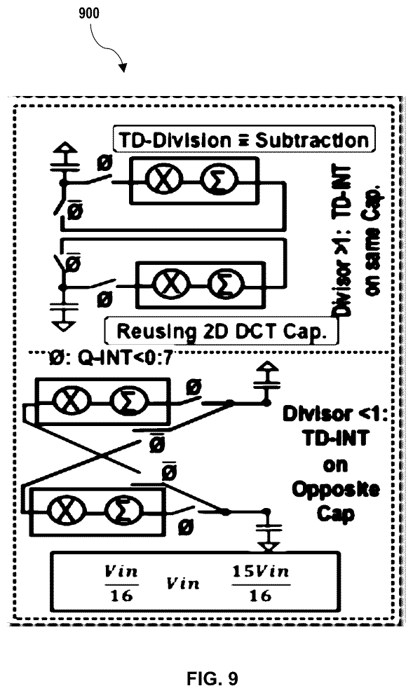

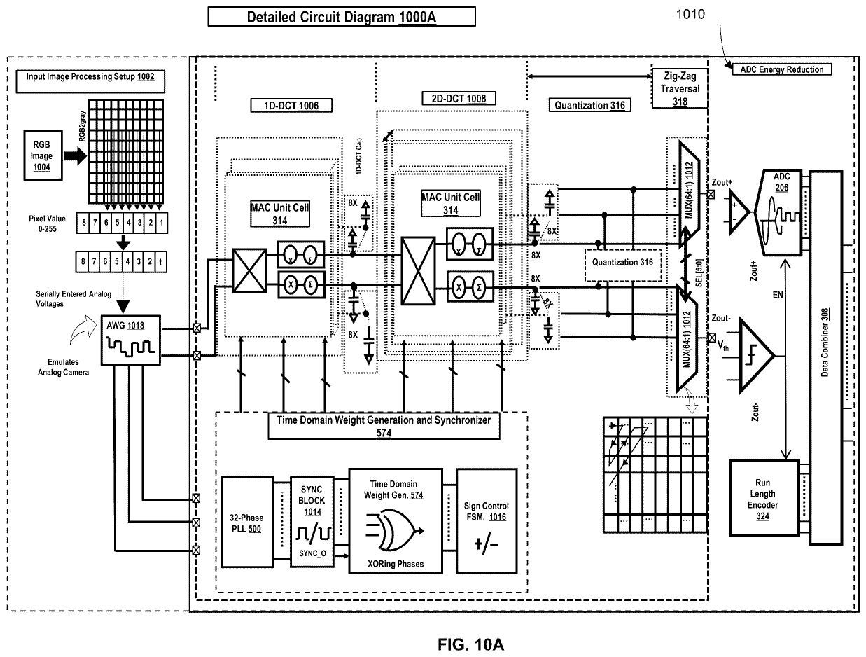

FIG. 9 illustrates an exemplary circuit diagram representation of an element-wise division unit 900, according to an example embodiment of the present disclosure. The division operation is performed using the repetitive subtraction operation. The 2D-DCT integration capacitor is used to perform the division operation for quantization step. Depending on the divisor value, if the divisor is >1, the time domain integration is performed on the same capacitor and vice versa for the case when divisor is >1. The division operation may be implemented using multiplication and subtraction operation. The 2D-DCT output capacitors are re-used for division operation for quantization. The Output of 2D-DCT (Vin) is sampled at the input of the MAC unit 314 and appropriate product of Vin is subtracted from Vin to realize division operation.

$$VOUT = \frac{{V}_{i n}}{X} = {V}_{i n} - \frac{Vin \cdot ( X - 1 )}{X} \qquad equation ( 4 )$$

$$\frac{Vin}{16} = Vin - \frac{15 Vin}{16} \qquad equation ( 5 )$$

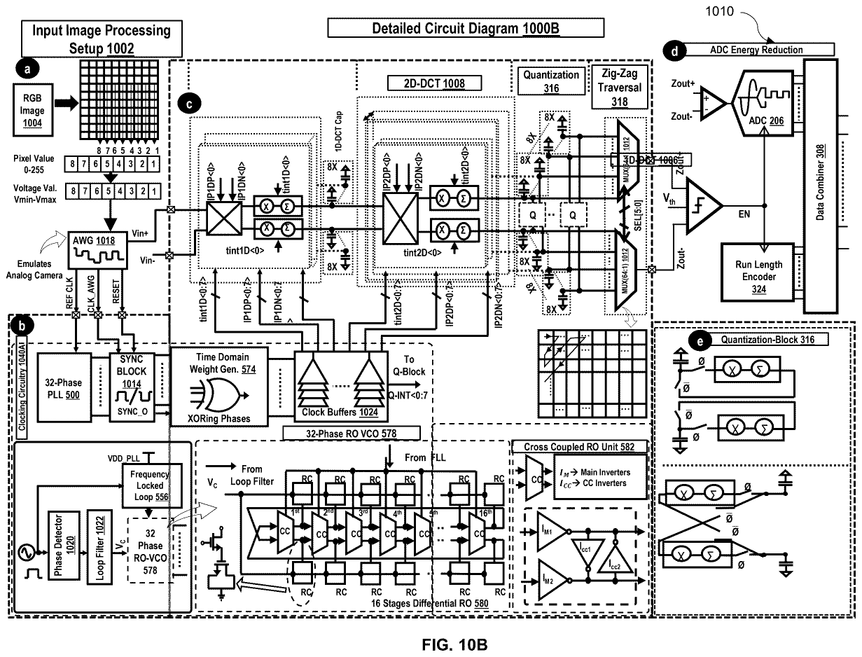

FIGS. 10A-B illustrates a diagram representation of time domain analog-to-jpeg compression system, according to an example embodiment of the present disclosure. As shown in FIG. 10A, the input image 1002 is divided into 8×8 pixel matrices 1004, with pixel values ranging from 0-255, mapped to the input voltage range. These voltages are sent to the Vin+ port of the IC using an Arbitrary Waveform Generator (AWG) 1018. The input sampling clock (CLK_AWG) is provided to the IC's clocking circuitry. The DCT circuit operates in 2 stages, processing an 8×8 matrix of pixels at a time. The first stage (1D-DCT) 1006 consists of 8-PD-MAC units 314. These units receive sampling clocks (IP1DP/N) and DCT weight pulses (tint1D), computing MAC output for one column in 8-cycles at the output capacitor. In the 9th cycle, these outputs are sampled to the next stage using 2D-DCT sampling clocks (IP2DP/N). The second stage (2D-DCT) 1008 comprises eight such 1D-DCT units, with DCT weight pulses (tint2D) provided at an 8× lower frequency. The DCT core computes the 2D-DCT of an 8×8 image block in 72 cycles (9 cycles×8 columns), resetting the 1D-DCT block after each column. Following 2D-DCT, Quantization 316 occurs using in-situ Q-blocks during the off-phase of the 72nd cycle. The Quantization unit 316 performs elementwise TD-division by sampling the 2D-DCT output to the input of a TD-MAC unit cell that subtracts an appropriate ratio of the output from the same 2DDCT output capacitor based on the Q50 matrix. This technique reduces area by eliminating the need for an extra capacitor by reusing the same 2D-DCT integration capacitors. The quantized samples are serialized such that significant samples are first followed by insignificant samples using a zig-zag traversal block 318 with an analog mux 1012 and a digital controller, which are then sent to the output. The output samples, when sent to an off-chip comparator, activate the ADC 206 only for significant samples (typically 5-10%), while Run-Length-Encoding (RLE) 324 is activated for insignificant samples, saving ADC 206 energy by digitizing only significant samples. The time domain weight generation and synchronizer block 574 selects appropriate clock phases from the 32-phase clock (for Clock and Data Alignment) and sends them to the TD-DCT weight generation block 574. This block generates the input sampling clocks, DCT weight time pulses and Quantization (Q) time pulses, which are then buffered and sent to the MAC units 314 in the DCT computation core, and the Q-unit 316.

FIG. 10B depicts working of MJPEG compression in the time domain, the circuit-diagram of the TD-dAJC unit 204, the input image processing setup and the post-processing. The input image 1002 is divided into 8×8 pixel matrices, with pixel values ranging from 0-255, mapped to the input voltage range. These voltages are sent to the Vin+ port of the IC using an Arbitrary Waveform Generator (AWG) 1018 as shown in FIG. 10B (a). The input sampling clock (CLK_AWG) is provided to the IC's clocking circuitry. The synchronizer block 1014 selects appropriate clock phases from the 32-phase clock (for Clock and Data Alignment) and sends them to the TD-DCT weight generation block 574. This block generates the input sampling clocks, DCT weight time pulses and Quantization (Q) time pulses, which are then buffered and sent to the MAC units 314 in the DCT computation core, and the Q-unit 316 as shown in FIG. 10B (b). The DCT circuit operates in 2 stages, processing an 8×8 matrix of pixels at a time as shown in FIG. 10B (c): the first stage (1D-DCT) 1006 consists of 8-PD-MAC units. These units receive sampling clocks (IP1DP/N) and DCT weight pulses (tint1D), computing MAC output for one column in 8-cycles at the output capacitor. In the 9th cycle, these outputs are sampled to the next stage using 2D-DCT sampling clocks (IP2DP/N). The second stage (2D-DCT) 1008 comprises eight such 1D-DCT units, with DCT weight pulses (tint2D) provided at an 8× lower frequency. The DCT core computes the 2D-DCT of an 8×8 image block in 72 cycles (9 cycles×8 columns), resetting the 1D-DCT block after each column. Following 2D-DCT, Quantization 316 occurs using in-situ Q-blocks 316 during the off-phase of the 72nd cycle. This block performs elementwise TD-division by sampling the 2D-DCT output to the input of a TD-MAC unit cell that subtracts an appropriate ratio of the output from the same 2DDCT output capacitor based on the Q50 matrix as shown in FIG. 10B (e). This technique reduces area by eliminating the need for an extra capacitor by reusing the same 2D-DCT integration capacitors. The quantized samples are serialized such that significant samples are first followed by insignificant samples using a zig-zag traversal block 318 with an analog mux 1012 and a digital controller, which are then sent to the output. The output samples, when sent to an off-chip comparator, activate the ADC 206 only for significant samples (typically 5-10%), while Run-Length-Encoding (RLE) 324 is activated for insignificant samples, saving ADC energy by digitizing only significant samples as shown in FIG. 10B(d).

FIG. 11 illustrates an example flow chart depicting a process 1100 of performing analog-to-MJPEG compression using time domain based mixed-signal processing techniques, according to an example embodiment of the present disclosure. At step 1102, the method 1100 includes receiving, by the data acquisition unit 302, analog voltage signals corresponding to pixel data from at least one sensor node. At step 1104, the method 1100 includes computing, by a multi-stage Discrete Cosine Transform (DCT) unit 310, multi-dimensional DCT coefficients corresponding to the pixel data in an analog domain. Further, at step 1106, the method 1100 includes generating, by a clock generation unit 312, time pulses corresponding to the multi-dimensional DCT coefficients and quantization matrix values. Further, at step 1108, the method 1100 includes performing, by a time-domain multiply-accumulate (MAC) unit 314, time-domain multiplication and division operations using the time pulses and a current signal to generate frequency-domain DCT outputs. Furthermore, at step 1110, the method 1100 includes generating, by a quantization unit 316, quantized outputs by performing element-wise division of the frequency-domain DCT outputs by the quantization matrix values using a plurality of capacitors for storing the frequency-domain DCT outputs.

Further, the method 1100 includes serializing, by a zig-zag traversal unit 318, the quantized outputs in an order prioritizing significant samples followed by insignificant samples. Further, the method 1100 includes comparing, by a comparator circuit 320, the serialized outputs to a threshold value to distinguish significant samples from insignificant samples. Furthermore, the method 1100 includes generating, by the comparator circuit 320, a control signal for selective digitization based on the comparison. Further, the method 1100 includes activating, by a switch circuit 322, an analog-to-digital converter (ADC) 206 to digitize the significant samples based on the control signal. Additionally, the method 1100 includes power gating, by the switch circuit 322, the ADC 206 for the insignificant samples. Moreover, the method 1100 includes counting, by a run-length encoding circuit 324, occurrences of the insignificant samples to output a count value representing the insignificant samples.

The method 1100 further includes digitizing, by the analog-to-digital converter (ADC) 206, the significant samples based on the control signal. Further, the method 1100 includes multiplexing, by a data combiner circuit 308, outputs of the ADC 206 and the run-length encoding circuit 324 to generate a MJPEG compressed digital output.

In performing the time-domain multiplication and division operations, the method 1100 includes converting, by a voltage-to-current conversion circuit, the analog voltage signals to an output current with a linear voltage-to-current relationship using an NMOS transistor and a source degeneration resistor. Further, the method 1100 includes regulating, by a switch circuit 322, the output current to a capacitor circuit based on the time pulses. Furthermore, the method 1100 includes storing, by the capacitor circuit, analog charge proportional to the output current. The output current is multiplied by a corresponding DCT coefficient and stored in a corresponding capacitor.

The method 1100 may be implemented in any suitable hardware, software, firmware, or combination thereof. The order in which the method 1100 is described is not intended to be construed as a limitation, and any number of the described method blocks may be combined or otherwise performed in any order to implement the method 1100 or an alternate method. Additionally, individual blocks may be deleted from the method 1100 without departing from the spirit and scope of the present disclosure described herein. Furthermore, the method 1100 may be implemented in any suitable hardware, software, firmware, or a combination thereof, that exists in the related art or that is later developed. The method 1100 describes, without limitation, the implementation of the system 200. A person of skill in the art will understand that method 1100 may be modified appropriately for implementation in various manners without departing from the scope and spirit of the disclosure.

In an embodiment, the system 200 may be connected to any external systems (not shown) for further processing of the MJPEG digitized bits. In one example embodiment, the system 200 may also include a hardware processor(s) (not shown) which may be coupled to a memory (not shown in FIGs.). The memory may include a plurality of modules/subsystems. The system 200 may be a hardware device including the hardware processor executing machine-readable program instructions for converting the direct analog samples to compressed digitized samples. Execution of the machine-readable program instructions by the hardware processor may enable the system 200 to convert the direct analog samples to compressed digitized samples. The “hardware” may comprise a combination of discrete components, an integrated circuit, an application-specific integrated circuit, a field-programmable gate array, a digital signal processor, or other suitable hardware. The “software” may comprise one or more objects, agents, threads, lines of code, subroutines, separate software applications, two or more lines of code, or other suitable software structures operating in one or more software applications or on one or more processors.

The hardware processor(s) may include, but are not limited to, microprocessors, microcomputers, microcontrollers, digital signal processors, central processing units, state machines, logic circuits, and/or any devices that manipulate data or signals based on operational instructions, and the like. Among other capabilities, the hardware processor may fetch and execute computer-readable instructions in the memory operationally coupled with the system 200 for performing tasks such as data processing, input/output processing, and/or any other functions. Any reference to a task in the present disclosure may refer to an operation being or that may be performed on data.

One of the ordinary skill in the art will appreciate that techniques consistent with the present disclosure are applicable in other contexts as well without departing from the scope of the disclosure.

Embodiments herein disclose a method of low power direct analog to JPEG compression for scenarios involving imaging sensor nodes that usually demand a restrained power budget, drawing on the recent push towards analog processing away from digital architectures. Particularly, the present disclosure depicts the end-to-end methodology for converting direct pixel data (analog image) to JPEG encoded information bits. Compared to digital processing, the analog scheme operates at reduced noise margins, offering similar functionality at lower power costs. The proposed analog compression scheme implements Time-mode capacitive integration circuits to perform the arithmetic operations in mixed signal domain and employs capacitors to store the data in the form of accumulated charge, embedding the information of DCT and Quantization (Q) matrices in time pulses. The proposed technique facilitates a significant reduction in the required power and improved speed facilitating better video resolution over the other state-of-the-art JPEG digital accelerators and can be further extended to other algorithms, applications, and sensor nodes, like video, biosensor nodes that currently accomplish processing in digital domain.

A method for low-energy image processing targeted towards JPEG compression is described, which utilizes Time-mode integration-based analog processing scheme for direct analog to JPEG (information) conversion. The end-to-end architecture for JPEG compression incorporates the required DCT and Q matrices implemented using time pulses generated using an on-chip PLL. The DCT coefficients are incorporated in the pulse width of the integrating clock. Owing to the analog architecture, the present scheme presents a low power alternative to the traditional digital architecture and a recent switched capacitor based analog domain MPJEG compression. The present direct analog to JPEG compression technique completes all the processing (arithmetic manipulations) in the analog domain and enables 206 only for significant JPEG image samples, power gating the ADC 206 for insignificant ones, saving more than 90% of the ADC power. The previous implementation using switched capacitor-based MAC and division computation to perform MJPEG compression has the demerits that the SC-based circuit occupy larger area, are prone to process variation and can handle low data rate thereby limiting the frame rate that it can handle.

The present system provides a linear voltage-to-current converter comprising: A voltage-to-current converter with a substantially linear voltage/current characteristic for input voltage signals smaller than a reference voltage signal level and up to the minimum voltage signal level generated by a DC power supply employed to drive the converter. The voltage-to-current converter includes an NMOS transistor with source degeneration, wherein the source degeneration resistor provides linearity and stability to the conversion process. The source degeneration resistors in the MAC units use a 5-bit binary controllability to compensate for process variations. The rms noise current contributions of MOS and resistor in the unit TD-MAC are used to determine the integrated rms noise voltage at the 2D-DCT output after 72 cycles, which is ~20 μV for an output capacitor of 200 fF. For an 8-bit ADC, the rms noise voltage must be below 50 μV to achieve a target SNR of 16 dB. Thus, the design meets the noise requirements.

Utilizing a larger output capacitor (~200 fF) aid in achieving lower rms noise voltage. The capacitor sizing helps handle non-idealities (clock feedthrough, charge injection) and (switching and KT/C) noise. In the measurement setup (not shown), a 4K RGB image is decomposed into 3-grayscale channels. The pixels are serialized to analog voltages and sent into the IC using an AWG. The compressed samples are captured and exported via an oscilloscope for analysis. The reconstructed image is generated by applying inverse-DCT on the measured analog samples in MATLAB and compared against the original image to verify compression fidelity. The results depict PSNR values of 30.1 dB for the MNIST dataset and 29.7 dB for 4K-checkerboard image.

The current mirrors reflect the output current of the voltage-to-current converter to provide a high impedance output to the converter to facilitate cascading. The input of the voltage-to-current converter employs a low threshold voltage (Vt) native transistor, ensuring high input impedance and allowing for better input voltage swing. The method further includes an analog processor that employs mixed-signal processing to enable image compression before digitizing into bits. The mixed-signal processing system for image processing and machine learning (such as image classification, object detection and the like), may include a linear voltage-to-current converters (V-I converters) with substantial linear voltage/current characteristics. Further, the mixed-signal processing system incudes capacitors for storing and manipulating analog charge. Also, the mixed-signal processing system includes current mirrors for accurately replicating current values.

Further, the mixed-signal processing system includes multiply-and-accumulate (MAC) unit that combines the outputs of the V-I converters and capacitors to perform multiplication and accumulation operations. Further, the mixed-signal processing system includes a division unit that utilizes the V-I converters and capacitors to perform division operations. The mixed-signal processing system operates seamlessly across analog and digital domains, enabling efficient processing of image data and can be extended to realizing machine learning algorithms.

The mixed-signal processing system uses a DCT coefficient storage mechanism using time pulses. Further, the mixed-signal processing system includes switches controlled by the time pulses, wherein each switch regulates the current from a V-I converter to charge a specific capacitor. The V-I converter converts the input voltage (representing the image signal) to a current, which is then multiplied by the corresponding DCT coefficient and stored in the capacitor associated with that coefficient. The mixed-signal processing system realizes efficient time-domain MAC operations for image compression and DCT processing. The mixed-signal processing system uses a pseudo differential architecture which helps in attaining the division operation and helps in cancelling the unwanted common mode signals present.

The mixed-signal processing system further includes a clocking and digital time pulse generating system for arithmetic operations. The clocking and digital time pulse generating system includes a low-power multiphase on-chip Phase-Locked Loop (PLL) configured to generate multiphase clock signals. Further, the clocking and digital time pulse generating system includes a digital circuit that receives the multiphase clock signals and generates time pulses corresponding to the values of Discrete Cosine Transform (DCT) matrix coefficients. The clocking and digital time pulse generating system utilizes the time pulses for multiply-and-accumulate (MAC) operations. The mixed-signal processing system enables efficient computation using DCT matrix values in the time domain.

The Quantization (Q) unit 316 realized using time-domain pseudo-differential MAC unit 314 comprises a mixed-signal processing system with a time-domain multiply-and-accumulate (MAC) unit 314. The MAC unit 314 performs division operations by sampling the input voltage at the input of a voltage-to-current converter (V-I converter) and using the resulting current to charge back the input capacitor. The quantization operation, required for JPEG compression, is realized by converting the division operation to a subtraction operation. The quantization unit 316 employs a pseudo-differential MAC architecture to achieve negative integration and subtraction. The same input capacitor stores the division result, eliminating the need for an extra capacitor for division. This in-situ division method saves area by 2× compared to traditional approaches. The 2D DCT, Quantization, zigzag traversing, and the run length encoder are implemented in mixed-signal domain to perform JPEG compression.

The 2D DCT is used in conjunction with mixed-signal circuits to transform the input image samples to DCT domain. The 2D-DCT circuit with its pseudo differential architecture is implemented with a plurality of several MAC units to perform such Multiply and accumulate and subtraction operation and achieve the required computation involving several mathematical operations. The pulse width of the integrating clock contains all the DCT coefficient values, can be extended to various multiplication, addition, subtraction, and division values. The mixed-signal processing system may use other analog memory elements including but not limited to ReRAM, PCM, floating gate memory, Flash memory and other non-volatile memories or the like.

Related to the zigzag traversing, use of analog MUX in conjunction with digital processor to serialize the outputs of Q-block to ensure the most significant samples are present in the beginning, followed by a long chain of insignificant ones (zeros). In conjunction with image compression techniques, use of comparator to distinguish the samples for generating the control signal that enables the ADC 206 and run length encoding blocks. Related to the run length encoder, the use of the counter with set/reset capabilities to count the occurrences of insignificant samples to send out the final count of the samples, instead of each sample itself. The use of ADC 206 only to digitize significant samples, saving energy. In conjunction with the run length encoder and ADC 206, the use of the data combiner block to enable multiplexing the outputs of ADC 206 and run length encoder to generate the JPEG encoded image bits.

The method of low-power direct analog to information conversion can be extended to other algorithms/applications to benefit from low-power compute of mixed-signal processing and ADC 206 energy savings. Related to the power-efficient mixed-signal processing, the use of a direct analog to information converter to process the sensed/acquired analog samples directly to information in the mixed signal domain before digitization.

The direct analog to information converter employs a linear voltage to current converter and time-domain integration-based MAC (multiply and accumulate) cells to perform the underlying Multiply-Accumulate (MAC) and division operations in mixed-signal domain for any given algorithm. Related to the time-domain mixed-signal computation technique, the use of the current integration onto a capacitor to perform arithmetical manipulations (multiplication, accumulation, and division).

The algorithms and applications encompass a wide range, including, for example, but not limited to, image and video processing tasks such as PNG, MJPEG, H.264, convolution filters, and object avoidance or recognition. This technique directly processes analog samples acquired from sensor nodes, such as biosensors and AR/VR nodes, resulting in processed digital output. The processing could be intended for compression, information generation or inference. In relation to the power efficiency of the ADC 206, the method's application powers the ADC 206 solely for substantial information samples. This approach removes the necessity to transform every raw sensed analog sample into digital bits for further processing.

What has been described and illustrated herein are examples of the present disclosure. The terms, descriptions, and figures used herein are set forth by way of illustration only and are not meant as limitations. Many variations are possible within the spirit and scope of the subject matter, which is intended to be defined by the following claims and their equivalents in which all terms are meant in their broadest reasonable sense unless otherwise indicated.

The written description describes the subject matter herein to enable any person skilled in the art to make and use the embodiments. The scope of the subject matter embodiments is defined by the claims and may include other modifications that occur to those skilled in the art. Such other modifications are intended to be within the scope of the claims if they have similar elements that do not differ from the literal language of the claims or if they include equivalent elements with insubstantial differences from the literal language of the claims.

The embodiments herein can comprise hardware and software elements. The embodiments that are implemented in software include but are not limited to, firmware, resident software, microcode, a. The functions performed by various modules described herein may be implemented in other modules or combinations of other modules. For the purposes of this description, a computer-usable or computer-readable medium can be any apparatus that can comprise, store, communicate, propagate, or transport the program for use by or in connection with the instruction execution system, apparatus, or device.

A description of an embodiment with several components in communication with each other does not imply that all such components are required. On the contrary, a variety of optional components are described to illustrate the wide variety of possible embodiments of the invention. When a single device or article is described herein, it will be apparent that more than one device/article (whether or not they cooperate) may be used in place of a single device/article. Similarly, where more than one device or article is described herein (whether or not they cooperate), it will be apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments of the invention need not include the device itself.

The illustrated steps are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, and the like., of those described herein) will be apparent to persons skilled in the relevant art(s) based on the teachings contained herein. Such alternatives fall within the scope and spirit of the disclosed embodiments. Also, the words “comprising,” “having,” “containing,” and “including,” and other similar forms are intended to be equivalent in meaning and be open-ended in that an item or items following any one of these words is not meant to be an exhaustive listing of such item or items or meant to be limited to only the listed item or items. It must also be noted that as used herein and in the appended claims, the singular forms “a”, “an”, and “the” include plural references unless the context clearly dictates otherwise.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the embodiments of the present invention are intended to be illustrative, but not limited, of the scope of the invention, which is outlined in the following claims.

What is claimed is:

1. A processing system for performing analog-to-MJPEG compression using time domain mixed-signal processing techniques, wherein the processing system comprises:
a data acquisition unit configured to receive analog voltage signals corresponding to pixel data from at least one sensor node;
a mixed-signal processing system coupled to the data acquisition unit, wherein the mixed-signal processing system comprises:
a multi-stage Discrete Cosine Transform (DCT) unit configured to compute multi-dimensional-DCT coefficients corresponding to the pixel data in analog domain;
a clock generation unit configured to generate time pulses corresponding to the multi-dimensional-DCT coefficients and quantization matrix values;
a time-domain multiply-accumulate (MAC) unit configured to perform time-domain multiplication and division operations using the time pulses and a current signal to generate frequency-domain DCT outputs which implements the matrix multiplication of the DCT coefficient matrix with the analog input voltage values matrix; and
a quantization unit configured to generate quantized outputs by performing element-wise division of the frequency-domain DCT outputs by a quantization matrix using a plurality of capacitors and time domain weight pulses, wherein the time domain weight pulses are equivalent to divisor values, wherein the plurality of capacitors store the frequency-domain DCT outputs.

2. The processing system of claim 1, wherein the mixed-signal processing system further comprises:
a zig-zag traversal unit comprising an analog multiplexer and a digital controller, wherein the zig-zag traversal unit is configured to serialize the quantized outputs in an order prioritizing significant samples followed by insignificant samples;
a comparator circuit configured to compare the serialized output to distinguish significant samples from insignificant samples based on a threshold value; and generate a control signal for selective digitization;
a switch circuit configured to activate an analog-to-digital converter (ADC) for the significant samples as determined by the comparator circuit; and power gate the ADC for insignificant samples; and
a run-length encoding circuit configured to count occurrences of the insignificant samples using a counter; and output a count value representing the insignificant samples.

3. The processing system of claim 1, further comprises:
the analog-to-digital converter (ADC) configured to selectively digitize the significant samples based on the control signal from the comparator circuit; and
a data combiner circuit configured to multiplex outputs of the ADC and the run-length encoding circuit to generate a MJPEG compressed digital output.

4. The processing system of claim 1, wherein the time-domain multiply-accumulate (MAC) unit comprises:
a voltage-to-current conversion circuit, wherein the voltage-to-current conversion circuit is configured to convert the analog voltage signals to an output current with a linear voltage-to-current relationship, wherein the output current is multiplied by a corresponding DCT coefficient and stored in a capacitor associated with respective coefficient, wherein the voltage-to-current conversion circuit comprises:
an NMOS transistor configured to convert the analog voltage signals to the output current, wherein the NMOS transistor operates over an input voltage range from below a reference voltage to a minimum voltage of a DC power supply; and
a source degeneration resistor connected to a source terminal of the NMOS transistor; wherein the source degeneration resistor provides resistance for linear voltage-to-current conversion.

5. The processing system of claim 1, wherein the mixed-signal processing system further comprises:
a capacitor circuit configured to store analog charge based on the output current;
a current mirror circuit configured to replicate the output current from the voltage to current conversion; and
a switch circuit configured to regulate the output current to the capacitor circuit based on the time pulses.

6. The processing system of claim 5, wherein the capacitor circuit comprises:
a plurality of capacitors configured to store analog charge proportional to the output current regulated by the switch circuit, wherein the output current is multiplied by a corresponding DCT coefficient and stored in a corresponding capacitor associated with respective DCT coefficient; and
an integration module configured to accumulate the analog charge proportional to the input voltage over a duration of the time pulses proportional to the weights.

7. The processing system of claim 6, wherein the plurality of capacitors are further configured to store a result of a division operation by subtracting a portion of an input value based on a quantization coefficient.

8. The processing system of claim 5, wherein the switch circuit comprises:
a plurality of switches each coupled between the voltage-to-current conversion circuit and a respective capacitor of the capacitor circuit; and
a control module configured to open and close the plurality of switches based on the time pulses.

9. The processing system of claim 1, wherein the time-domain multiply-accumulate (MAC) unit is configured to perform one multiplication and accumulation operation for a plurality of operands in plurality of clock cycles to generate the frequency-domain DCT outputs, wherein the frequency-domain DCT outputs are proportional to accumulated charge on corresponding capacitors of the capacitor circuit.

10. The processing system of claim 1, wherein the quantization unit is configured to:
sample the frequency-domain DCT outputs of the time-domain multiply-accumulate (MAC) unit using a sampling rate; and
perform a division operation by charging the capacitor circuit to subtract a portion of the sampled output based on a quantization matrix.

11. The processing system of claim 1, wherein the quantization unit reuses a capacitor of the capacitor circuit of the DCT stage to store a result of the division operation, and operates in three phases:
a sampling phase to sample a voltage from the frequency-domain DCT outputs of the time-domain multiply-accumulate (MAC) unit;
an integration module to convert the sampled voltage to a current and charge the capacitor; and
a reset phase to reset a capacitor circuit to zero.

12. The processing system of claim 1, wherein the time-domain multiply-accumulate (MAC) unit comprises:
a first stage comprising a plurality of pseudo-differential MAC units, wherein the plurality of pseudo-differential MAC units are configured to compute a one-dimensional DCT (1D-DCT) for one column of a N*N image block in a plurality of clock cycles; and
a second stage comprising a plurality of first-stage units configured to compute a two-dimensional DCT (2D-DCT) for the N*N image block in the plurality of clock cycles.

13. The processing system of claim 12, wherein the plurality of pseudo-differential MAC units are configured to process the analog voltage signals corresponding to positive and negative DCT coefficients, wherein:
for a positive DCT coefficient, a first input voltage (Vin+) is connected to a positive input (VINP) and a second input voltage (Vin−) is connected to a negative input (VINN); and
for a negative DCT coefficient, the first input voltage (Vin+) is connected to the negative input (VINN) and the second input voltage (Vin−) is connected to the positive input (VINP).

14. The processing system of claim 1, wherein the clock generation unit is configured to generate at least one of input sampling clocks, DCT weight time pulses for 1D-DCT operations at each cycle of a base clock, DCT weight time pulses for 2D-DCT operations at each N cycles of the base clock; and wherein the time pulses embed information of a DCT matrix and a quantization matrix.

15. The processing system of claim 5, wherein the capacitor circuit is configured to perform multiplication and division operations by:
segmenting a multiplication operation into multiple addition operations; and
segmenting a division operation into multiple subtraction operations, using the plurality of pseudo-differential MAC units with switching between sampling capacitors.

16. The processing system of claim 1, wherein the clock generation unit comprises:
an on-chip Phase-Locked Loop (PLL) configured to generate multiphase clock signals; and
a digital circuit configured to receive the multiphase clock signals and generate the time pulses corresponding to values of a Discrete Cosine Transform (DCT) matrix.

17. A method for performing analog-to-MJPEG compression using time-domain mixed-signal processing techniques, the method comprising:
receiving, by a data acquisition unit, analog voltage signals corresponding to pixel data from at least one sensor node;
computing, by a multi-stage Discrete Cosine Transform (DCT) unit, multi-dimensional DCT coefficients corresponding to the pixel data in an analog domain;
generating, by a clock generation unit, time pulses corresponding to the multi-dimensional DCT coefficients and quantization matrix values;
performing, by a time-domain multiply-accumulate (MAC) unit, time-domain multiplication and division operations using the time pulses and a current signal to generate frequency-domain DCT outputs which implements the matrix multiplication of the DCT coefficient matrix with the analog input voltage values matrix; and
generating, by a quantization unit, quantized outputs by performing element-wise division of the frequency-domain DCT outputs by the quantization matrix values using a plurality of capacitors and time domain weight pulses, wherein the time domain weight pulses are equivalent to divisor values, wherein the plurality of capacitors store the frequency-domain DCT outputs.

18. The method of claim 17, further comprising:
serializing, by a zig-zag traversal unit, the quantized outputs in an order prioritizing significant samples followed by insignificant samples;
comparing, by a comparator circuit, the serialized outputs to a threshold value to distinguish significant samples from insignificant samples;
generating, by the comparator circuit, a control signal for selective digitization based on the comparison;
activating, by a switch circuit, an analog-to-digital converter (ADC) to digitize the significant samples based on the control signal;
power gating, by the switch circuit, the ADC for the insignificant samples; and
counting, by a run-length encoding circuit, occurrences of the insignificant samples to output a count value representing the insignificant samples.

19. The method of claim 18, further comprising:
digitizing, by the analog-to-digital converter (ADC), the significant samples based on the control signal; and
multiplexing, by a data combiner circuit, outputs of the ADC and the run-length encoding circuit to generate a MJPEG compressed digital output.

20. The method of claim 17, wherein performing the time-domain multiplication and division operations comprises:
converting, by a voltage-to-current conversion circuit, the analog voltage signals to an output current with a linear voltage-to-current relationship using a native transistor and a source degeneration resistor;
regulating, by a switch circuit, the output current to a capacitor circuit based on the time pulses; and
storing, by the capacitor circuit, analog charge proportional to the output current, wherein the output current is multiplied by a corresponding DCT coefficient and stored in a corresponding capacitor.
